(19) United States
(12) Patent Application Publication
(10) Pub. No.: US 2026/0082986 A1
(43) Pub. Date: Mar. 19, 2026

(54) SEMICONDUCTOR PACKAGE AND MANUFACTURING METHOD OF THE SAME, AND MANUFACTURING METHOD OF SEMICONDUCTOR DEVICE FOR RECONSTITUTION PROCESS

(71) Applicant: SAMSUNG ELECTRONICS CO., LTD., Suwon-si (KR)

(72) Inventors: Changbo LEE, Suwon-si (KR); Pil-Kyu KANG, Suwon-si (KR); Jae-Wha PARK, Suwon-si (KR)

(73) Assignee: SAMSUNG ELECTRONICS CO., LTD., Suwon-si (KR)

(21) Appl. No.: 19/202,680

(22) Filed: May 8, 2025

(30) Foreign Application Priority Data
Sep. 19, 2024 (KR) 10-2024-0126948

(51) Int. Cl. H01L 23/31; H01L 23/00; H01L 23/48

(52) U.S. Cl. CPC H10W 74/141; H10W 20/20; H10W 72/0198; H10W 90/792

(57) ABSTRACT

A method of manufacturing a semiconductor device includes preparing a device substrate including a plurality of active regions, the device substrate including a substrate, a semiconductor device portion on a first surface of the substrate, and a first bonding layer on the semiconductor device portion, where the first bonding layer includes a first pad and a first insulation layer, forming a preliminary substrate by forming a sacrificial layer on the first bonding layer, bonding the preliminary substrate to a carrier substrate such that the sacrificial layer faces the carrier substrate, forming a second bonding layer on a second surface of the substrate, the second bonding layer including a second pad and a second insulation layer, and cutting the preliminary substrate to separate the plurality of active regions.

### CROSS-REFERENCE TO RELATED APPLICATION

This application is based on and claims priority to Korean Patent Application No. 10-2024-0126948, filed on Sep. 19, 2024, in the Korean Intellectual Property Office, the disclosure of which are incorporated by reference herein in its entirety.

### BACKGROUND

### 1. Field

The present disclosure relates to a semiconductor package and a manufacturing method of the same, and a manufacturing method of a semiconductor device for a reconstitution process.

### 2. Description of Related Art

A semiconductor device may have a small size while performing various functions, and is thus widely used in various electronic industries. As advancements are made in the electronic industry, research is continuing on a manufacturing process and a packaging process of the semiconductor device to enhance performance of the semiconductor device and reduce a size of the semiconductor device.

As a semiconductor device become smaller, there may be a limit to a process applicable to manufacture and package the semiconductor device. Accordingly, the process of manufacturing and packaging the semiconductor device may be complicated and a process error may increase, which may lower reliability of the semiconductor device.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Example embodiments provide a manufacturing method of a semiconductor device for a reconstitution process that may be capable of enhancing productivity and reliability, a manufacturing method of a semiconductor package including the same, and a semiconductor package manufactured by the manufacturing method of the semiconductor package.

Additional aspects will be set forth in part in the description which follows and, in part, will be apparent from the description, or may be learned by practice of the presented embodiments.

According to an aspect of an example embodiment, a semiconductor package may include a first semiconductor device, a second semiconductor device on the first semiconductor device and, in a plan view, having an area smaller than an area of the first semiconductor device, and a side insulation portion on a side surface of the second semiconductor device, the side insulation portion including an inorganic insulating material, where each of the first semiconductor device and the second semiconductor device includes a substrate having a first surface and a second surface opposite to the first surface, a semiconductor device portion on the first surface of the substrate, a first bonding layer on the semiconductor device portion, the first bonding layer including a first pad and a first insulation layer, an insertion insulation layer on the second surface of the substrate, a second bonding layer on the insertion insulation layer, the second bonding layer including a second pad and a second insulation layer, and a through connector penetrating the substrate and connecting the first pad to the second pad, where the insertion insulation layer includes a material that is different from a material of at least a portion of the second insulation layer, and in the second semiconductor device, an edge of the insertion insulation layer is between the second surface of the substrate and the second bonding layer.

According to an aspect of an example embodiment, a method of manufacturing a semiconductor device may include preparing a device substrate including a plurality of active regions, the device substrate including a substrate, and a semiconductor device portion and a first bonding layer on the semiconductor device portion, where the first bonding layer includes a first pad and a first insulation layer, forming a preliminary substrate by forming a sacrificial layer on the first bonding layer, bonding the preliminary substrate to a carrier substrate such that the sacrificial layer faces the carrier substrate, forming a second bonding layer on a second surface of the substrate, the second bonding layer including a second pad and a second insulation layer, and cutting the preliminary substrate to separate the plurality of active regions.

According to an aspect of an example embodiment, a method of manufacturing a semiconductor device may include forming a first semiconductor portion, where the first semiconductor portion includes a plurality of first semiconductor devices, forming a second semiconductor portion, where the second semiconductor portion includes a plurality of second semiconductor devices, and bonding the second semiconductor portion on the first semiconductor portion, where the forming of the second semiconductor portion includes preparing a device substrate, where the device substrate includes a substrate, and a semiconductor device portion and a first bonding layer on the semiconductor device portion, the first bonding layer including a first pad and a first insulation layer, forming a preliminary substrate by forming a sacrificial layer on the first bonding layer, preliminarily bonding the preliminary substrate to a carrier substrate such that the sacrificial layer faces the carrier substrate, forming a second bonding layer on a second surface of the substrate, the second bonding layer including a second pad and a second insulation layer, cutting the preliminary substrate to separate the plurality of second semiconductor devices, bonding the plurality of second semiconductor devices to a reconstitution carrier substrate such that the second bonding layer of each of the plurality of second semiconductor devices faces the reconstitution carrier substrate, and forming a gap-fill layer in at least one space between the plurality of second semiconductor devices on the reconstitution carrier substrate, and where the gap-fill layer includes an inorganic insulating material.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a cross-sectional view of a semiconductor package according to one or more embodiments;

FIG. 2 is an enlarged cross-sectional view of a portion A in FIG. 1 according to one or more embodiments;

FIG. 3 is an enlarged cross-sectional view of a portion B in FIG. 1 according to one or more embodiments;

FIG. 4 to FIG. 16 are cross-sectional views illustrating a manufacturing method of a semiconductor package according to one or more embodiments;

FIG. 17 is a cross-sectional view of a semiconductor package according to one or more embodiments;

FIG. 18 to FIG. 21 are cross-sectional views illustrating a manufacturing method of a semiconductor package according to one or more embodiments;

FIG. 22 is a cross-sectional view of a semiconductor package according to one or more embodiments;

FIG. 23 to FIG. 27 are cross-sectional views illustrating a manufacturing method of a semiconductor package according to one or more embodiments; and

FIG. 28 is a cross-sectional view of a chiplet package including a semiconductor package according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Further, since a size and/or a thickness of a portion, a region, a member, a unit, a layer, a film, a substrate, etc., illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, etc., may be enlarged or exaggerated for convenience of explanation and/or simple illustration.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

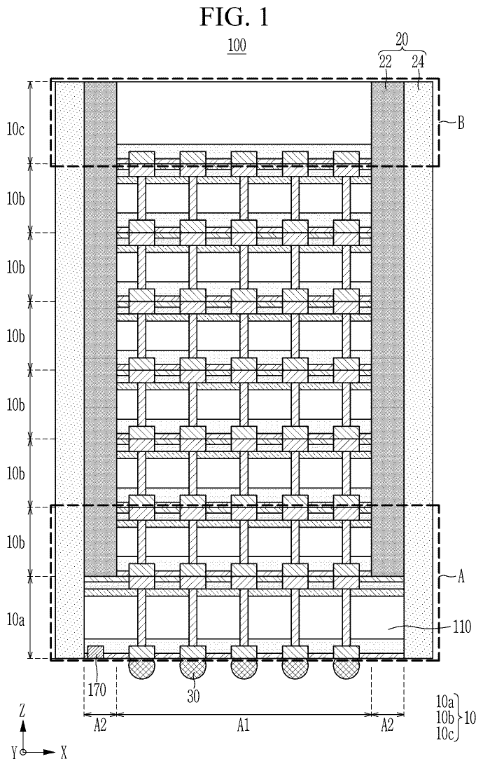

FIG. 1 is a cross-sectional view of a semiconductor package according to one or more embodiments.

Referring to FIG. 1, a semiconductor package 100 according to one or more embodiments may include a plurality of semiconductor devices 10 that are stacked in a thickness direction (the Z-axis direction) of the semiconductor package 100. The semiconductor package 100 may further include a side insulation portion 20 that is disposed on at least a portion of a side surface of the plurality of semiconductor devices 10.

In one or more embodiments, the plurality of semiconductor devices 10 may include a first semiconductor device 10a and a second semiconductor device 10b that is disposed on the first semiconductor device 10a. The plurality of semiconductor devices 10 may further include a third semiconductor device 10c that is disposed on the second semiconductor device 10b. The semiconductor device 10 may be referred to as a semiconductor die, a semiconductor element, etc.

In one or more embodiments, the semiconductor package 100 may be a stacked memory package or a stacked memory chip formed by stacking and bonding the plurality of semiconductor devices 10 in the thickness direction (the Z-axis direction). In the stacked memory package or the stacked memory chip, data merging of the plurality of semiconductor devices 10 may be possible. For example, the semiconductor package 100 may be a high bandwidth memory (HBM) device. The high bandwidth memory device may include the plurality of semiconductor devices 10 and include a plurality of memory channels, thereby achieving a relatively short delay time and a high bandwidth simultaneously. By stacking the plurality of semiconductor devices 10 in the thickness direction, an area of the semiconductor package 100 may be reduced.

In one or more embodiments, the plurality of semiconductor devices 10 may include a volatile memory or a non-volatile memory. For example, the semiconductor device 10 may include a dynamic random access memory (DRAM) as a volatile memory. In one or more embodiments, the semiconductor device 10 may include a static random access memory (SRAM), a thyristor random access memory (TRAM), a zero-capacitor random access memory (ZRAM), etc., as a volatile memory. In one or more embodiments, the semiconductor device 10 may include a flash memory, a resistive random access memory (RRAM), etc., as a non-volatile memory.

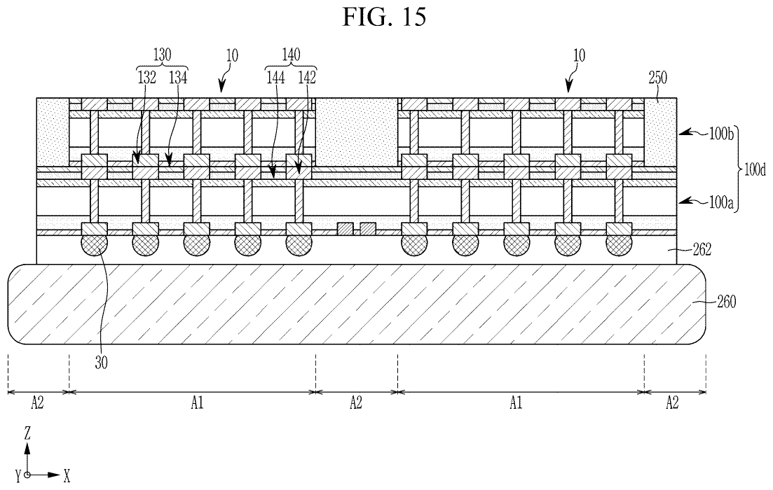

The first semiconductor device 10a may be disposed at a lower portion (e.g., a lowermost portion) of the semiconductor package 100, and an interconnection member 30 may be disposed on a lower surface or an outer surface of the first semiconductor device 10a. The first semiconductor device 10a may be a lowermost portion in a stacking process of bonding the plurality of semiconductor devices 10, and may be a portion of a first semiconductor portion 100a (refer to FIG. 15) where a cutting process, a reconstitution process, and a gap-fill process have not been performed. In a stacking process, the first semiconductor portion 100a (refer to FIG. 15) where the cutting process, the reconstitution process, and the gap-fill process are not performed may be disposed at a lowermost portion, thereby stably performing the stacking process and reducing process cost.

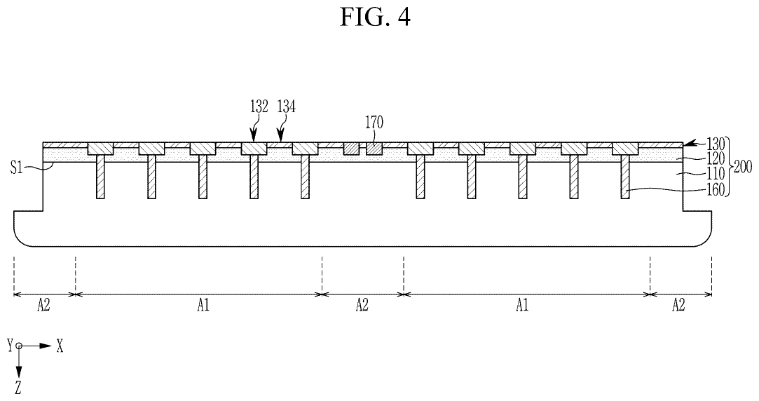

Accordingly, the first semiconductor device 10a may include an active region A1 and an outer region A2 that is disposed outside the active region A1. The outer region A2 may include a substrate 110 that includes a semiconductor material, like the active region A1. In the outer region A2, a dummy pattern 170 may disposed. The dummy pattern 170 and the outer region A2 will be described later in more detail with reference to FIG. 4.

In one or more embodiments, a thickness of the first semiconductor device 10a may be greater than a thickness of the second semiconductor device 10b. Thereby, the first semiconductor device 10a may stably support the second semiconductor device 10b. However, the embodiments are not limited thereto. In one or more embodiments, the thickness of the first semiconductor device 10a may be same as or less than the thickness of the second semiconductor device 10b.

One or a plurality of second semiconductor devices 10b may be disposed on the first semiconductor device 10a. The third semiconductor device 10c may be disposed at an upper portion of the semiconductor package 100 on one or the plurality of second semiconductor devices 10b.

The second semiconductor device 10b may be disposed between the first semiconductor device 10a and the third semiconductor device 10c. The second semiconductor device 10b may be a portion of a second semiconductor portion 100b (refer to FIG. 15). The second semiconductor portion 100b may be disposed on the first semiconductor portion 100a (refer to FIG. 15) in the stacking process of bonding the plurality of semiconductor devices 10, and may include a plurality of second semiconductor devices 10b and a gap-fill layer 250 (refer to FIG. 15). The third semiconductor device 10c may be disposed at an upper portion (e.g., an uppermost portion) of the semiconductor package 100. The third semiconductor device 10c may be a portion of a third semiconductor portion. The third semiconductor portion may be disposed on the second semiconductor portion 100b (refer to FIG. 15) in the stacking process of bonding the plurality of semiconductor devices 10, and may include a plurality of third semiconductor devices 10c and a gap-fill layer 250 (refer to FIG. 15). The second semiconductor portion 100c (refer to FIG. 15) and the third semiconductor portion may be portions where the cutting process, the reconstitution process, and the gap-fill process have been performed.

In one or more embodiments, a thickness of the third semiconductor device 10c may be greater than a thickness of the second semiconductor device 10b. Thereby, mechanical stability of the semiconductor package 100 may be enhanced. However, the embodiments are not limited thereto. In one or more embodiments, the thickness of the third semiconductor device 10c may be same as or less than the thickness of the second semiconductor device 10b.

In one or more embodiments, each of the second semiconductor device 10b and the third semiconductor device 10c may include a portion that corresponds to the active region A1, and may not include a portion that corresponds to the outer region A2. That is, the second semiconductor device 10b and the third semiconductor device 10c may only be disposed within the active region A1 in a cross-sectional view. Accordingly, in a plan view, the second semiconductor device 10b and the third semiconductor device 10c may be disposed such that the third semiconductor device 10c covers an upper surface of the second semiconductor device 10b, and an area of the second semiconductor device 10b and an area of the third semiconductor device 10c may be substantially the same.

The first semiconductor device 10a may include the active region A1 and the outer region A2. Accordingly, in a plan view, the first semiconductor device 10a may be wider than the second semiconductor device 10b and the third semiconductor device 10c, and may include a portion that extends into the outer region A2. Accordingly, an area (e.g., a planar area) of the second semiconductor device 10b and/or an area (e.g., a planar area) of the third semiconductor device 10c may be less than an area (e.g., a planar area) of the first semiconductor device 10a.

At least a portion (e.g., a first side insulation portion 22) of the side insulation portion 20 may be disposed on a side surface of the second semiconductor device 10b and/or the third semiconductor device 10c on the portion of the first semiconductor device 10a that extends into the outer region A2.

In one or more embodiments, the side insulation portion 20 that is disposed on the side surface of the plurality of semiconductor devices 10 may include a first side insulation portion 22 and a second side insulation portion 24. The first side insulation portion 22 may be disposed on the portion of the first semiconductor device 10a that extends into the outer region A2. The second side insulation portion 24 may be disposed outside the first semiconductor device 10a, the second semiconductor device 10b, and/or the third semiconductor device 10c at an outside of the first side insulation portion 22.

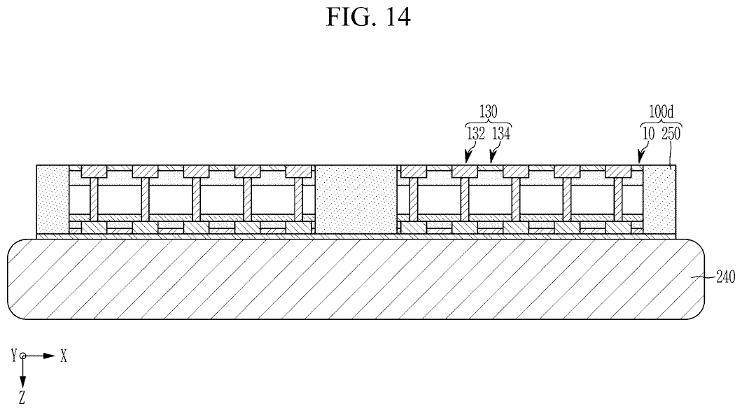

The first side insulation portion 22 may be formed of a gap-fill layer 250 (refer to FIG. 14) that fills a space between the semiconductor devices 10 in a process of forming a semiconductor portion 100d (refer to FIG. 14). Accordingly, the first side insulation portion 22 may not include the substrate 110 that includes a semiconductor material, and may not include the dummy pattern 170.

In one or more embodiments, the first side insulation portion 22 that is formed of the gap-fill layer 250 (refer to FIG. 14) may include or be formed of an inorganic insulation portion that includes an inorganic insulating material. The first side insulation portion 22 may include or be formed of at least one of oxide, nitride, carbonitride, oxycarbide, oxynitride, and oxycarbonitride. For example, the first side insulation portion 22 may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). For example, the first side insulation portion 22 may include or be formed of silicon oxide (SiOx). The first side insulation portion 22 that includes the inorganic insulating material may be discriminated from a molding layer, a resin layer, etc., that includes an organic insulating material.

In one or more embodiments, the first side insulation portion 22 that is disposed on the side surface of the second semiconductor device 10b and/or the third semiconductor device 10c on the portion of the first semiconductor device 10a that extends into the outer region A2 may include or be formed of an inorganic insulating material, due to a semiconductor portion 100d (refer to FIG. 15) that is used in the stacking process of bonding the plurality of semiconductor devices 10. The semiconductor portion 100d may be formed by performing a reconstitution process of the second semiconductor device 10b or may be formed by performing a reconstitution process of the third semiconductor device 10c. For example, the stacking process of bonding the plurality of semiconductor devices 10 may be a wafer-on-wafer (WOW) bonding process. This will be described later in more detail in a manufacturing method of the semiconductor package 100.

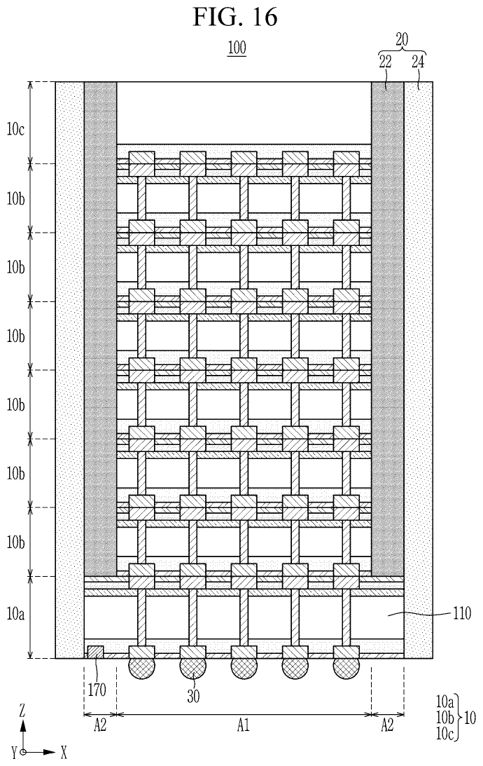

The second side insulation portion 24 may be formed after a dividing process (refer to FIG. 16), and may mechanically and/or chemically protect the plurality of semiconductor devices 10. The dividing process may be performed after the stacking process to divide a bonded structure including the semiconductor portions 100d into a plurality of semiconductor packages 100.

The second side insulation portion 24 may include or be formed of an insulating material. The second side insulation portion 24 may include or be formed of an inorganic insulating material or an organic insulating material.

The second side insulation portion 24 may include or be formed of at least one of oxide, nitride, carbonitride, oxycarbide, oxynitride, and oxycarbonitride as an inorganic insulating material. For example, the second side insulation portion 24 may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx).

The second side insulation portion 24 may include or be formed of a molding material as an organic insulating material. For example, the second side insulation portion 24 may include or be formed of a thermosetting resin such as an epoxy resin, a thermoplastic resin such as polyimide, a resin that includes an organic filler and/or a glass fiber, an epoxy molding compound, and so on.

In FIG. 1, it is illustrated as an example that a boundary is between the first side insulation portion 22 and the second side insulation portion 24. However, the embodiments are not limited thereto. When the first side insulation portion 22 and the second side insulation portion 24 include a same material, a boundary may not be present between the first side insulation portion 22 and the second side insulation portion 24. In this instance, the side insulation portion 20 that includes the first side insulation portion 22 and the second side insulation portion 24 may have a relatively small width at the side surface of the first semiconductor device 10a and may have a relatively large width at the side surface of the second semiconductor device 10b and/or the third semiconductor device 10c.

However, the embodiments are not limited to a material, a shape, etc., of the side insulation portion 20, the first side insulation portion 22, or the second side insulation portion 24. A material, a shape, etc., of the side insulation portion 20, the first side insulation portion 22, or the second side insulation portion 24 may be variously modified.

In FIG. 1, it is illustrated as an example that the semiconductor package 100 includes eight semiconductor devices 10. However, the embodiments are not limited thereto, and a number of the semiconductor devices 10 that are included in the semiconductor package 100 may be four or more (e.g., eight or more, as an example, sixteen or more).

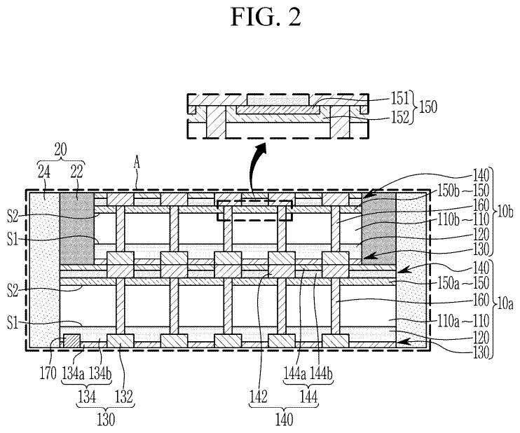

The interconnection member 30 may be disposed on the lower surface or the outer surface of the first semiconductor device 10a (that is a surface of the first semiconductor device 10a opposite to the second semiconductor device 10b). For example, the interconnection member 30 may be electrically connected to a first pad 132 (refer to FIG. 2) that is disposed at the lower surface or the outer surface of the first semiconductor device 10a.

The interconnection member 30 may have a shape or a type of a bump, a land, a ball, or a pin. The interconnection member 30 may include or be formed of at least one of tin, lead, bismuth, silver, copper, aluminum, tungsten, nickel, manganese, cobalt, titanium, tantalum, ruthenium, beryllium, indium, molybdenum, magnesium, rhenium, and gallium, or include or be formed of an alloy thereof. For example, the interconnection member 30 may be a solder bump that includes or is formed of tin or that includes or is formed of an alloy that includes tin. However, the embodiments are not limited thereto, and a shape, a type, a material, etc., of the interconnection member 30 may be variously modified.

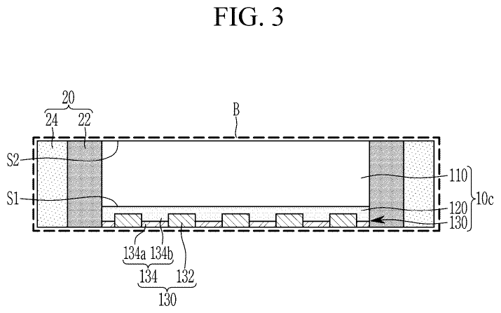

FIG. 2 is an enlarged cross-sectional view of a portion A in FIG. 1 according to one or more embodiments. FIG. 3 is an enlarged cross-sectional view of a portion B in FIG. 1 according to one or more embodiments.

Referring to FIG. 1 to FIG. 3, each of the first semiconductor device 10a and the second semiconductor device 10b may include a substrate 110, a semiconductor device portion 120, a first bonding layer 130, a second bonding layer 140, a through connector 160, and an insertion insulation layer 150. The substrate 110 may have a first surface S1 and a second surface S2 that are opposite to each other. The semiconductor device portion 120 may be disposed on the first surface S1 of the substrate 110. The first bonding layer 130 may be disposed on the semiconductor device portion 120, and include a first pad 132 and a first insulation layer 134. For example, at least a portion of the first bonding layer 130 may be disposed on the semiconductor device portion 120. For example, a portion of the first insulation layer 134 may be disposed on the semiconductor device portion 120, and/or another portion of the first insulation layer 134 may be formed of a portion of the semiconductor device portion 120. The second bonding layer 140 may be disposed on the second surface S2 of the substrate 110, and include a second pad 142 and a second insulation layer 144. The through connector 160 may pass through or penetrate the substrate 110 to electrically connect the first pad 132 and the second pad 142. The insertion insulation layer 150 may be disposed between the substrate 110 and the second bonding layer 140. The insertion insulation layer 150 may include a material that is different from a material of at least a portion of the second insulation layer 144.

In one or more embodiments, the substrate 110 may include or be formed of a semiconductor material. For example, the substrate 110 may include or be formed of a single-crystalline or polycrystalline semiconductor (e.g., Si, Ge, SiGe, etc.). For example, the substrate 110 may be a silicon substrate.

The semiconductor device portion 120 that is disposed on the first surface S1 of the substrate 110 may include a semiconductor element, and a wiring that is electrically connected to the semiconductor element. The semiconductor device portion 120 may include a memory device or a memory element of storing data and a wiring included therein, but the embodiments are not limited thereto.

In one or more embodiments, the plurality of semiconductor devices 10 may be bonded to each other through hybrid bonding that includes metal bonding and insulation-layer bonding. More particularly, the plurality of semiconductor devices 10 may be bonded to each other through the hybrid bonding that includes the metal bonding between the first pad 132 and the second pad 142 and the insulation-layer bonding between the first insulation layer 134 (e.g., a first bonding insulation layer 134a) and the second insulation layer 144 (e.g., a second bonding insulation layer 144a). By bonding the plurality of semiconductor devices 10 through the hybrid bonding, a connection bump may be omitted and a wiring pitch may be reduced.

The first pad 132 and the second pad 142 may be for the metal bonding and/or an electrical connection of the plurality of semiconductor devices 10. The first pad 132 and/or the second pad 142 may include or be formed of metal, for example, at least one of copper, aluminum, tungsten, nickel, gold, tin, manganese, cobalt, titanium, tantalum, ruthenium, and beryllium, or may include or be formed of an alloy thereof. For example, the first and second pads 132 and 142 may include copper, and the plurality of semiconductor devices 10 may be bonded to each other through copper-to-copper bonding. For example, the first and second pads 132 and 142 may directly contact each other and be bonded to each other through copper-to-copper bonding.

In one or more embodiments, the first insulation layer 134 may be disposed at a periphery of the first pad 132 in the first bonding layer 130. The second insulation layer 144 may be disposed at a periphery of the second pad 142 in the second bonding layer 140. The first insulation layer 134 and/or the second insulation layer 144 may include a single layer or a plurality of layers.

In one or more embodiments, the first insulation layer 134 may include a first bonding insulation layer 134a, and include a first base insulation layer 134b. For example, the first bonding insulation layer 134a may be disposed on the semiconductor device portion 120. For example, a portion of the first base insulation layer 134b may be disposed on the semiconductor device portion 120, and/or another portion of the first base insulation layer 134b may be formed of a portion of the semiconductor device portion 120 (e.g., an insulation layer included in the semiconductor device portion 120). The second insulation layer 144 may include a second bonding insulation layer 144a, and include a second base insulation layer 144b. In one or more embodiments, the first insulation layer 134 (e.g., the first bonding insulation layer 134a or the first base insulation layer 134b) or the second insulation layer 144 (e.g., the second bonding insulation layer 144a or the second base insulation layer 144b) may include or be formed of an inorganic insulating material.

The first bonding insulation layer 134a and/or the second bonding insulation layer 144a may be for the insulation-layer bonding of the plurality of semiconductor devices 10. The first bonding insulation layer 134a and/or the second bonding insulation layer 144a may include or be formed of an insulating material to be bonded to each other, for example, at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). For example, the first bonding insulation layer 134a and the second bonding insulation layer 144a may include or be formed of a same insulating material. However, the embodiments are not limited thereto.

The first base insulation layer 134b and/or the second base insulation layer 144b may include a chemically stable insulating material to electrically insulate the first pad 132 and/or the second pad 142. The first base insulation layer 134b and/or the second base insulation layer 144b may include or be formed of a material that is different from a material of the first bonding insulation layer 134a and/or the second bonding insulation layer 144a. For example, the first bonding insulation layer 134a and/or the second bonding insulation layer 144a may include or be formed of silicon carbonitride (SiCNx), and the first base insulation layer 134b and/or the second base insulation layer 144b may include or be formed of silicon oxide (SiOx). However, the embodiments are not limited thereto.

A stacking structure, a material, etc., of the first insulation layer 134 or the second insulation layer 144 may be variously modified. For example, the first base insulation layer 134b and/or the second base insulation layer 144b may be omitted.

The insertion insulation layer 150 that is disposed between the second bonding layer 140 and the substrate 110 may include a material different from at least a portion of the second insulation layer 144. At least a portion of the insertion insulation layer 150 may act as an etch stopping layer in a process of forming the second pad 142. Accordingly, the insertion insulation layer 150 may be referred to as an etch stopping layer.

In one or more embodiments, the insertion insulation layer 150 may include a first layer 151 that includes an insulating material different from a material of at least one (e.g., each) of the second bonding insulation layer 144a and the second base insulation layer 144b, and the first layer 151 may be an etch stopping layer. The insertion insulation layer 150 may further include a second layer 152 that includes a material different from a material of the first layer 151. The first layer 151 may be adjacent to the second insulation layer 144 than the second layer 152.

For example, the first layer 151 may include or be formed of nitride (e.g., silicon nitride (SiNx)) and include or be formed of a nitride layer (e.g., a silicon nitride layer), and the second layer 152 may include or be formed of an insulating material that is more chemically stable than a material of the first layer 151. For example, the second layer 152 may include or be formed of oxide (silicon oxide (SiOx)) and may include or be formed of an oxide layer (e.g., a silicon oxide layer). However, the embodiments are not limited thereto, and materials of the first layer 151 and the second layer 152 may be variously modified.

The through connector 160 may pass through or penetrate the substrate 110, and electrically connect the semiconductor device portion 120 to the second pad 142 or electrically connect the first pad 132 to the second pad 142. For example, the through connector 160 may include a through silicon via (TSV) and/or a through last via (TLV). The through connector 160 that is included in the first semiconductor device 10a and the through connector 160 that is included in the second semiconductor device 10b may be disposed at a same position in a plan view. Thereby, a connection path may be reduced and a signal loss may be reduced. However, the embodiments are not limited thereto.

The through connector 160 may include a conductive portion that includes or is formed of a metallic material. For example, the conductive portion of the through connector 160 may include or be formed of at least one of copper, aluminum, tungsten, nickel, gold, tin, manganese, cobalt, titanium, tantalum, ruthenium, and beryllium or may include or be formed of alloy thereof. An insulation layer for an electrical insulation from the substrate 110 may be disposed on an outer side surface of the conductive portion of the through connector 160. The insulation layer that is disposed on the outer side surface of the conductive portion of the through connector 160 may include or be formed of any of various insulating materials, for example, silicon oxide (SiOx), silicon nitride (SiNx), silicon oxynitride (SiONx), etc.

The third semiconductor device 10c may include a substrate 110 that has a first surface S1 and a second surface S2, a semiconductor device portion 120 that is disposed on the first surface S1 of the substrate 110, and a first bonding layer 130 that is disposed on the semiconductor device portion 120 and includes a first pad 132 and a first insulation layer 134. A description of the substrate 110, the semiconductor device portion 120, and the first bonding layer 130 of the first semiconductor device 10a and/or the second semiconductor device 10b may be applied to the substrate 110, the semiconductor device portion 120, and the first bonding layer 130 of the third semiconductor device 10c.

The third semiconductor device 10c may not include portions that correspond to the second bonding layer 140, the through connector 160, and the insertion insulation layer 150. Thereby, a manufacturing process may be simplified and structural stability may be enhanced. However, the third semiconductor device 10c may further include a portion that corresponds to at least one of the second bonding layer 140, the through connector 160, or the insertion insulation layer 150.

The first semiconductor device 10a, the second semiconductor device 10b, and the third semiconductor device 10c may be electrically connected to each other through the through connector 160, and a wiring of the semiconductor device portion 120.

In one or more embodiments, the insertion insulation layer 150 of the first semiconductor device 10a and the insertion insulation layer 150 of the second semiconductor device 10b may have a same shape. Here, having the same shape may refer that a planar shape and a cross-sectional shape are same, and may have a difference in area (e.g., a planar area).

Hereinafter, the substrate 110 of the first semiconductor device 10a may be referred to as a first substrate 110a, the substrate 110 of the second semiconductor device 10b may be referred to as a second substrate 110b, the insertion insulation layer 150 of the first semiconductor device 10a may be referred to as a first insertion insulation layer 150a, and the insertion insulation layer 150 of the second semiconductor device 10b may be referred to as a second insertion insulation layer 150b.

In the first semiconductor device 10a, the entirety of the first insertion insulation layer 150a may be disposed between the second surface S2 of the first substrate 110a and the second bonding layer 140. For example, in the first semiconductor device 10a, the entirety of the first insertion insulation layer 150a may be disposed on a same plane between the second surface S2 of the first substrate 110a and the second bonding layer 140. For example, in the first semiconductor device 10a, the entirety of the first insertion insulation layer 150a may have a flat planar shape that is spaced apart from the first surface S1 of the first substrate 110a or the first bonding layer 130 between the second surface S2 of the first substrate 110a and the second bonding layer 140.

In the first semiconductor device 10a, the first insertion insulation layer 150a may not include a portion that is disposed on a side surface of the first substrate 110a and a portion that is adjacent to the first surface S1 of the first substrate 110a or the first bonding layer 130. That is, in the first semiconductor device 10a, the first insertion insulation layer 150a may not include a bent portion, a curved portion, or a portion that extends to another surface.

Accordingly, in the first semiconductor device 10a, an edge of the first insertion insulation layer 150a may be disposed between the second surface S2 of the first substrate 110a and the second bonding layer 140. For example, in the first semiconductor device 10a, an entire edge of the first insertion insulation layer 150a may be disposed between the second surface S2 of the first substrate 110a and the second bonding layer 140. In a cross-sectional view, in the first semiconductor device 10a, one edge (e.g., a left edge) of the first insertion insulation layer 150a may be disposed on a same side surface as one edge (e.g., a left edge) of the first substrate 110a, the other edge (e.g., a right edge) of the first insertion insulation layer 150a may be disposed on a same side surface as the other edge (e.g., a right edge) of the first substrate 110a, and the first insertion insulation layer 150a may have a shape that extends from one edge of the first substrate 110a to the other edge of the first substrate 110a. In other words, the edges of the first insertion insulation layer 150a may be substantially vertically coplanar with respective side surfaces of the first substrate 110a.

In one or more embodiments, in the first semiconductor device 10a, the first insertion insulation layer 150a may contact the second bonding layer 140. For example, the first insertion insulation layer 150a may contact at least a portion of one surface (a lower surface in FIG. 2) of the second bonding layer 140 adjacent to the second surface S2 of the first substrate 110a. That is, the first insertion insulation layer 150a may contact at least a portion of one surface (a lower surface in FIG. 2) of the second pad 142 and one surface (a lower surface in FIG. 2) of the second insulation layer 144 that are adjacent to the second surface S2 of the first substrate 110a. However, the embodiments are not limited thereto, and an additional layer may be disposed between the first insertion insulation layer 150a and the second bonding layer 140 in the first semiconductor device 10a.

In the second semiconductor device 10b, an entirety of the second insertion insulation layer 150b may be disposed between the second surface S2 of the second substrate 110b and the second bonding layer 140. For example, in the second semiconductor device 10b, the entirety of the second insertion insulation layer 150b may be disposed on a same plane between the second surface S2 of the second substrate 110b and the second bonding layer 140. For example, in the second semiconductor device 10b, the entirety of the second insertion insulation layer 150b may have a flat planar shape that is spaced apart from the first surface S1 of the second substrate 110b or the first bonding layer 130 between the second surface S2 of the second substrate 110b and the second bonding layer 140. That is, in the second semiconductor device 10b, the entirety of the second insertion insulation layer 150b may have a flat planar shape that is spaced apart from the first semiconductor device 10a. Accordingly, the entirety of the second insertion insulation layer 150b in the second semiconductor device 10b may be parallel to the first insertion insulation layer 150a in the first semiconductor device 10a, and the second insertion insulation layer 150b in the second semiconductor device 10b may not include a portion that extends in a direction crossing the first insertion insulation layer 150a of the first semiconductor device 10a.

In the second semiconductor device 10b, the second insertion insulation layer 150b may not include a portion that is disposed on a side surface of the second substrate 110b and a portion that is adjacent to the first surface S1 of the second substrate 110b or the first bonding layer 130. That is, in the second semiconductor device 10b, the second insertion insulation layer 150b may not include a portion that is adjacent to (e.g. contacting) the first semiconductor device 10a. That is, in the second semiconductor device 10b, the second insertion insulation layer 150b may not include a bent portion, a curved portion, or a portion that extends to another surface.

Accordingly, in the second semiconductor device 10b, an edge of the second insertion insulation layer 150b may be disposed between the second surface S2 of the second substrate 110b and the second bonding layer 140. For example, in the second semiconductor device 10b, an entire edge of the second insertion insulation layer 150b may be disposed between the second surface S2 of the second substrate 110b and the second bonding layer 140. In a cross-sectional view, in the second semiconductor device 10b, one edge (e.g., a left edge) of the second insertion insulation layer 150b may be disposed on a same side surface as one edge (e.g., a left edge) of the second substrate 110b, the other edge (e.g., a right edge) of the second insertion insulation layer 150b may be disposed on a same side surface as the other edge (e.g., a right edge) of the second substrate 110b, and the second insertion insulation layer 150b may have a shape that extends from one edge of the second substrate 110b to the other edge of the second substrate 110b. That is, the edges of the second insertion insulation layer 150b may be substantially vertically coplanar with the respective side surfaces of the second substrate 110b.

In one or more embodiments, in the second semiconductor device 10b, the second insertion insulation layer 150b may contact the second bonding layer 140. For example, the second insertion insulation layer 150b may contact at least a portion of one surface (a lower surface in FIG. 2) of the second bonding layer 140 that is adjacent to the second surface S2 of the second substrate 110b. That is, the first insertion insulation layer 150a may contact at least portions of one surface (a lower surface in FIG. 2) of the second pad 142 and one surface (a lower surface in FIG. 2) of the second insulation layer 144 that are adjacent to the second surface S2 of the second substrate 110b. However, the embodiments are not limited thereto, and an additional layer may be disposed between the second insertion insulation layer 150b and the second bonding layer 140 in the second semiconductor device 10b.

The area of the second semiconductor device 10b may be less than the area of the first semiconductor device 10a, and an area (e.g., a planar area) of the second insertion insulation layer 150b may be less than an area (e.g., a planar area) of the first insertion insulation layer 150a. That is, the second insertion insulation layer 150b may have a shape same as a shape of the first insertion insulation layer 150a and may have an area smaller than an area of the first insertion insulation layer 150a. An entirety of the second insertion insulation layer 150b may have a flat planar shape that is spaced apart from the first semiconductor device 10a.

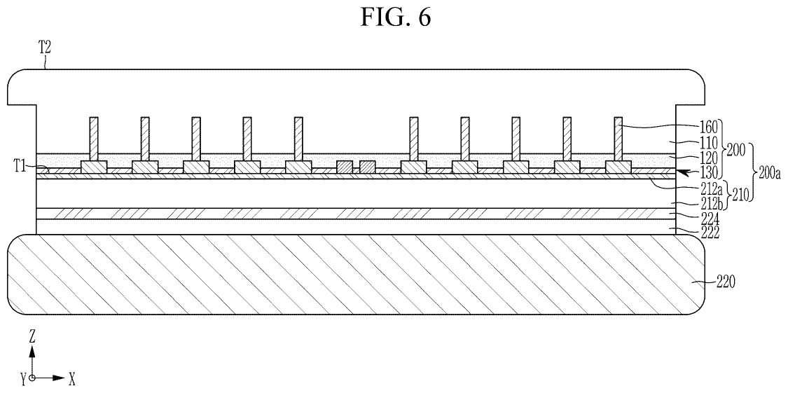

In one or more embodiments, the second semiconductor device 10b that includes the second pad 142 and the second insulation layer 144 may be formed on a carrier substrate 220 (refer to FIG. 6), and then, a cutting process and a reconstitution process may be performed. Thereby, the second insertion insulation layer 150b may have the above shape. This will be described later in more detail in a manufacturing method of the semiconductor package 100 with reference to FIG. 4 to FIG. 16. In the above description, it is described as an example that the first insertion insulation layer 150a and the second insertion insulation layer 150b have a same shape. However, the embodiments are not limited thereto. The second insertion insulation layer 150b may have the above shape, and the first insertion insulation layer 150a may have a shape different from the above shape.

FIG. 4 to FIG. 16 are cross-sectional views illustrating a manufacturing method of a semiconductor package according to one or more embodiments. Description of aspects that are the same as or similar to those described above may be omitted.

A manufacturing method of a semiconductor package 100 according to one or more embodiments may include a stacking process and further include a dividing process. In the stacking process, a second semiconductor portion 100b that includes a plurality of second semiconductor devices 10b may be bonded to a first semiconductor portion 100a that includes a plurality of first semiconductor devices 10a. In the dividing process, a bonded structure where the second semiconductor portion 100b is bonded to the first semiconductor portion 100a may be divided to an individual semiconductor package 100. The stacking process may further include a process of bonding a third semiconductor portion that includes a plurality of third semiconductor devices 10c (refer to FIG. 1) on the second semiconductor portion 100b. The first semiconductor portion 100a, the second semiconductor portion 100b, or the third semiconductor portion that includes the plurality of semiconductor devices 10 may be referred to as a semiconductor portion 100d.

A process of forming the second semiconductor portion 100b will be described with reference to FIG. 4 to FIG. 14, and a process of forming the first semiconductor portion 100a and a process of the third semiconductor portion will be described with reference to at least a part of FIG. 4 to FIG. 14. Unless otherwise described in the description referring to FIG. 4 to FIG. 14, the semiconductor device 10 may correspond to the second semiconductor device 10b. Referring to FIG. 15 and FIG. 16, a stacking process will be described.

First, as illustrated in FIG. 4, a device substrate 200 may be prepared. The device substrate 200 may include a substrate 110, a semiconductor device portion 120 and a first bonding layer 130 that are disposed at or on a first surface S1 of a substrate 110, and a through connector 160 that passes through or penetrates at least a portion of the substrate 110. The first bonding layer 130 may include a first pad 132 and a first insulation layer 134. A process, a method, an order, etc., of forming the device substrate 200 may be variously modified, and the embodiments are not limited thereto.

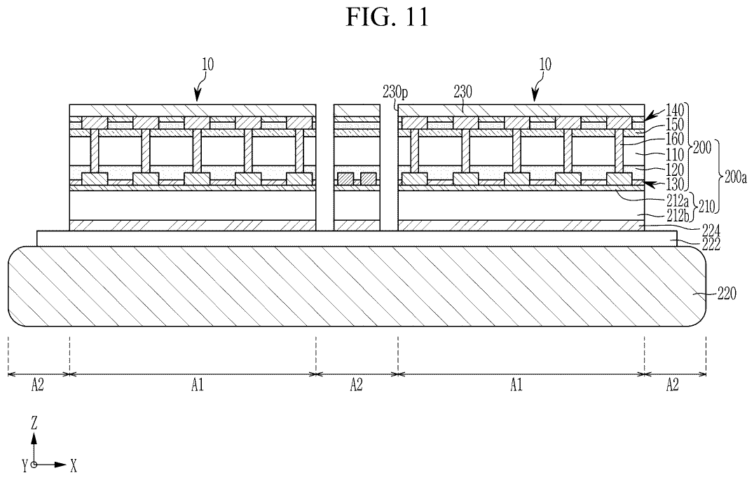

In a plan view, the substrate 110 or the device substrate 200 may include the plurality of active regions A1 that correspond to portions where a plurality of semiconductor devices 10 (refer to FIG. 11) will be disposed, and an outer region A2 that is disposed outside the plurality of active regions A1. The outer region A2 may be configured to include a portion that is cut in a cutting process of individually cutting the structure into the plurality of semiconductor devices 10. The outer region A2 may be referred to as an external region, a scribe lane, a scribe line, a cutting region, a divided region, etc.

In one or more embodiments, a dummy pattern 170 may be disposed in the outer region A2. The dummy pattern 170 may include at least one of an align pattern, an overlayer pattern, a measurement pattern, and a test element group (TEG). The align pattern may be configured to be aligned with a mask used in a manufacturing process. The overlay pattern may be configured to check an alignment status of a layer formed in a previous process and a layer formed in a current process. The measurement pattern may be configured to check a thickness, a critical dimension, a shape, etc., of each layer, and may include an optical pattern, for example, an optical critical dimension (OCD) pattern. The test element group may be configured to check performance during a manufacturing process or after the manufacturing process. However, the embodiments are not limited to a kind of the dummy pattern 170 in the outer region A2. Accordingly, any of various dummy patterns 170 may be provided in the outer region A2.

In FIG. 4, it is illustrated as an example that the device substrate 200 includes the plurality of active regions A1 that correspond to the plurality of semiconductor devices 10, respectively. Thereby, the plurality of semiconductor devices 10 may be formed together using one device substrate 200, and a manufacturing process may be simplified. However, the embodiments are not limited thereto.

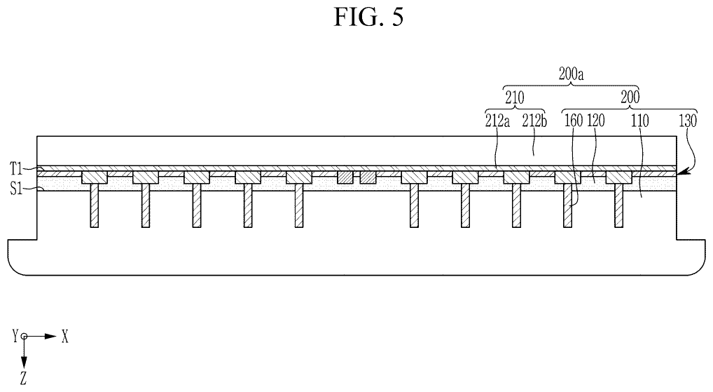

In FIG. 4, it is illustrated as an example that a trim process is performed at a side surface of the device substrate 200. Thereby, stability may be enhanced in subsequent processes (e.g., a bonding process that bonds a preliminary substrate 200a (refer to FIG. 5) including the device substrate 200 to a carrier substrate 220 (refer to FIG. 6), a process of removing a portion of the device substrate 200, etc.). However, the embodiments are not limited thereto, and various modifications are possible.

Subsequently, as illustrated in FIG. 5, a preliminary substrate 200a may be formed by forming a sacrificial layer 210 on the device substrate 200 (e.g., on a first surface T1 of the device substrate 200 that is adjacent to a first surface S1 of the substrate 110 or on the first bonding layer 130). The preliminary substrate 200a may refer to a structure including the sacrificial layer 210 and the device substrate 200.

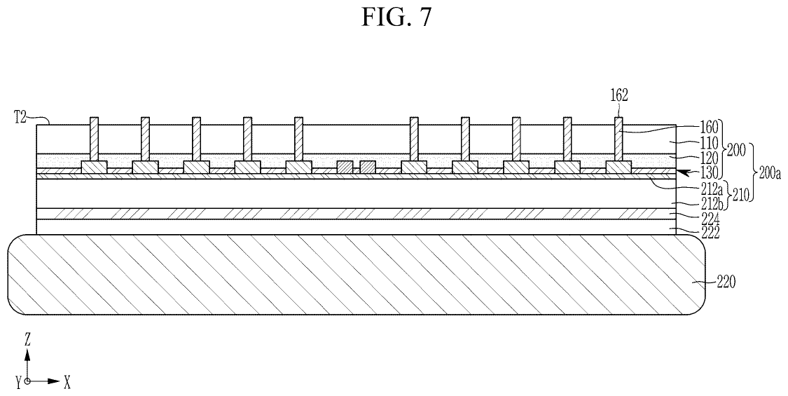

In one or more embodiments, the preliminary substrate 200a may have a sufficient thickness by the sacrificial layer 210 in a thickness direction (the Z-axis direction) of a semiconductor package or the preliminary substrate 200a, after a thinning process (refer to FIG. 7) of removing a portion of the device substrate 200 (e.g., a portion of the substrate 110). For example, the preliminary substrate 200a may have a sufficient thickness capable of being handled by the sacrificial layer 210 after the thinning process. The handling of the preliminary substrate 200a may include all of picking the preliminary substrate 200a, moving the preliminary substrate 200a to a certain location, placing the preliminary substrate 200a at a certain location, etc.

In one or more embodiments, the sacrificial layer 210 may include a base sacrificial layer 212b, and may further include a protective sacrificial layer 212a that is disposed between the base sacrificial layer 212b and the device substrate 200. For example, the protective sacrificial layer 212a and the base sacrificial layer 212b may be sequentially formed on the first surface T1 of the device substrate 200 by any of various processes (e.g., a deposition process, such as a chemical vapor deposition process, etc.) that are performed on the first surface T1 of the device substrate 200.

The base sacrificial layer 212b may have a relatively large thickness so that the sacrificial layer 210 has a sufficient thickness. The protective sacrificial layer 212a may protect the first surface T1 of the device substrate 200 (e.g., the first bonding layer 130) in a process of removing the sacrificial layer 210 (e.g., the base sacrificial layer 212b) etc. The protective sacrificial layer 212a may have a thickness less than a thickness of the base sacrificial layer 212b.

In one or more embodiments, the base sacrificial layer 212b may include an insulating sacrificial layer that includes or is formed of an insulating material and/or a semiconductor sacrificial layer that includes or is formed of a semiconductor material. The insulating sacrificial layer may include or be formed of at least one of oxide, nitride, carbonitride, oxycarbide, oxynitride, and oxycarbonitride. For example, the insulating sacrificial layer may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). When the insulating sacrificial layer includes or is formed of the above material, the insulating sacrificial layer may have chemical stability and may be formed by an easy process. Further, in a planarization process performed in a gap-fill process, the insulating sacrificial layer may be easily removed together with a gap-fill layer 250 (refer to FIG. 14). However, the embodiments are not limited thereto, and the insulating sacrificial layer may include or be formed of any of various insulating materials. The semiconductor sacrificial layer may include or be formed of silicon, germanium, or silicon-germanium that has a polycrystalline, amorphous, or epitaxial structure. The semiconductor sacrificial layer may include or be formed of an undoped semiconductor material. In one or more embodiments, the semiconductor sacrificial layer may include or be formed of an n-type or p-type doped semiconductor material. However, the embodiments are not limited thereto, and the semiconductor sacrificial layer may include or be formed of any of various materials.

In one or more embodiments, the base sacrificial layer 212b may be easily formed by a deposition process. When the base sacrificial layer 212b includes or is formed of the insulating material, stability may be enhanced in a manufacturing process, and the base sacrificial layer 212b may act as a stopping layer in an etching process, a chemical mechanical polishing process, a grinding process, etc. When the base sacrificial layer 212b includes or is formed of the semiconductor material, the base sacrificial layer 212b may include a material same as or similar to a material of the substrate 110 that is cut in a cutting process (refer to FIG. 11) of individually separating the plurality of semiconductor devices 10 included in the preliminary substrate 200a. Thereby, the sacrificial layer 210 (e.g., the base sacrificial layer 212b) may be easily removed in the cutting process, and process time of the cutting process may be reduced.

In one or more embodiments, the protective sacrificial layer 212a may include or be formed of an insulating material that is different from a material of at least a portion of the base sacrificial layer 212b. The protective sacrificial layer 212a may include or be formed of at least one of oxide, nitride, carbonitride, oxycarbide, oxynitride, and oxycarbonitride. For example, the protective sacrificial layer 212a may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx) that is different from a material of at least a portion of the base sacrificial layer 212b. When the protective sacrificial layer 212a includes or is formed of the above material, the protective sacrificial layer 212a may be easily removed together the gap-fill layer 250 in the planarization process performed in the gap-fill process.

For example, the base sacrificial layer 212b may include or be formed of silicon oxide (SiOx), and the protective sacrificial layer 212a may include or be formed of at least one of silicon nitride (SiNx), silicon carbonitride (SiCNx), silicon oxycarbide (SiOCx), silicon oxynitride (SiONx), or silicon oxycarbonitride (SiOCNx).

In FIG. 5, it is illustrated as an example that the sacrificial layer 210 includes one base sacrificial layer 212b and one protective sacrificial layer 212a. However, the embodiments are not limited thereto. The base sacrificial layer 212b may include a plurality of layers that include different materials, or the protective sacrificial layer 212a may include a plurality of layers that include different materials, or the protective sacrificial layer 212a may be omitted. A material of the base sacrificial layer 212b and/or the protective sacrificial layer 212a may be variously modified.

In one or more embodiments, a planarization process that planarizes a surface of the sacrificial layer 210 may be performed after the process of forming the sacrificial layer 210. The planarization process may be performed by a grinding process and/or a chemical mechanical polishing process. By the planarization process, a surface planarity of the sacrificial layer 210 may be enhanced and the preliminary substrate 200a may be stably bonded to a carrier substrate 220 (refer to FIG. 6).

In one or more embodiments, a thickness of the sacrificial layer 210 or the base sacrificial layer 212b may be 100 um or less (e.g., 20 um to 100 um, as an example, 50 um to 100 um). If the thickness of the sacrificial layer 210 or the base sacrificial layer 212b is 20 um or more (e.g., 50 um or more), the preliminary substrate 200a may have a sufficient thickness capable of being handled by the sacrificial layer 210 after a thinning process. For example, a thickness of the device substrate 200 after the thinning process may be 50 um or less (e.g., 30 um or less). Even in a case, the preliminary substrate 200a may have a thickness greater than 50 um (e.g., 100 um to 150 um) by the sacrificial layer 210, and the preliminary substrate 200a may have a sufficient thickness capable of being handled. If the thickness of the sacrificial layer 210 or the base sacrificial layer 212b is greater than 100 um, process time of a sacrificial-layer removal process of removing the sacrificial layer 210 or the base sacrificial layer 212b may increase. However, the embodiments are not limited thereto, and the thickness of the sacrificial layer 210 or the base sacrificial layer 212b may be greater than 100 um, or less than 50 um (e.g., less than 20 um).

For example, the thickness of the sacrificial layer 210 may be greater than a thickness of the substrate 110 after the thinning process (refer to FIG. 7). However, the embodiments are not limited thereto, and the thickness of the sacrificial layer 210 may be same as or less than the thickness of the substrate 110 after the thinning process.

Subsequently, as illustrated in FIG. 6 to FIG. 11, a semiconductor device 10 (e.g., a plurality of semiconductor devices 10) may be formed by positioning the preliminary substrate 200a on a carrier substrate 220 and forming a second bonding layer 140 that includes a second pad 142 and a second insulation layer 144 on a second surface S2 of the substrate 110.

More particularly, as illustrated in FIG. 6, the preliminary substrate 200a may be bonded (e.g., be temporarily or preliminarily bonded) on the carrier substrate 220.

The carrier substrate 220 may include or be formed of any of various materials. For example, the carrier substrate 220 may include or be formed of glass, a resin, a semiconductor material, etc., but the embodiments are not limited to a material of the carrier substrate 220.

In one or more embodiments, an adhesive layer 222 and a release layer 224 may be disposed on the carrier substrate 220.

The adhesive layer 222 may include or be formed of any of various materials capable of bonding the carrier substrate 220 and the sacrificial layer 210. For example, the adhesive layer 222 may include glue that includes an adhesive material, a bonding material, or a sticky material, or include a tape that includes an adhesive material, a bonding material, or a sticky material. The adhesive material, the bonding material, or the sticky material may include or be formed of an organic material. In one or more embodiments, the adhesive layer 222 may include or be formed of any of an inorganic material. For example, the adhesive layer 222 may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). The adhesive layer 222 that includes or is formed of the inorganic material may have a thickness smaller than a thickness of the adhesive layer 222 that includes or is formed of the organic material. Thereby, the adhesive layer 222 that includes or is formed of the inorganic material may minimize a thickness deviation or a thickness difference of the adhesive layer 222. Thereby, a process error in a process of exposing an end 162 (refer to FIG. 7) of the through connector 160 may be reduced more.

The release layer 224 may include or be formed of a release material capable of being separated, peeled off, or removed by light, heat, etc. The release layer 224 may include or be formed of any of various release materials, and the embodiments are not limited thereto.

The preliminary substrate 200a may be bonded (e.g., be temporarily or preliminarily bonded) on the carrier substrate 220 so that the sacrificial layer 210 (e.g., the protective sacrificial layer 212a and the base sacrificial layer 212b) of the preliminary substrate 200a faces the carrier substrate 220 (e.g., the adhesive layer 222 and the release layer 224).

In FIG. 6, it is illustrated as an example that the adhesive layer 222 is disposed on the carrier substrate 220 and the release layer 224 is disposed on the adhesive layer 222. However, the embodiments are not limited thereto. In one or more embodiments, the release layer 224 may be disposed on the carrier substrate 220, and the adhesive layer 222 may be disposed on the release layer 224. In one or more embodiments, at least one of the adhesive layer 222 and the release layer 224 may be omitted, or a layer other than the adhesive layer 222 and the release layer 224 may be further included.

Subsequently, as illustrated in FIG. 7, a thinning process of reducing a thickness of the preliminary substrate 200a may be performed. In one or more embodiments, in the thinning process of reducing the thickness of the preliminary substrate 200a, an end 162 of the through connector 160 (e.g., an end 162 of the through connector 160 that is adjacent to a second surface T2 of the preliminary substrate 200a) may be exposed. That is, in the thinning process, a portion of the preliminary substrate 200a adjacent to the second surface T2 of the preliminary substrate 200a in the thickness direction (the Z-axis direction) may be removed, and the end 162 of the through connector 160 may protrude from the second surface T2 of the preliminary substrate 200a. The thinning process may be performed by any of various processes (e.g., an etch back process using dry etching or wet etching). The thinning process may include a chemical mechanical polishing process, a grinding process, etc.

In one or more embodiments, in the thinning process of reducing the thickness of the preliminary substrate 200a, the process of exposing the end 162 of the through connector 160 may be performed together. Accordingly, a number of an etching process, a chemical mechanical polishing process, a grinding process, etc. performed at the second surface T2 of the preliminary substrate 200a, before forming the end 162 of the through connector 160, may be reduced, thereby reducing a process error.

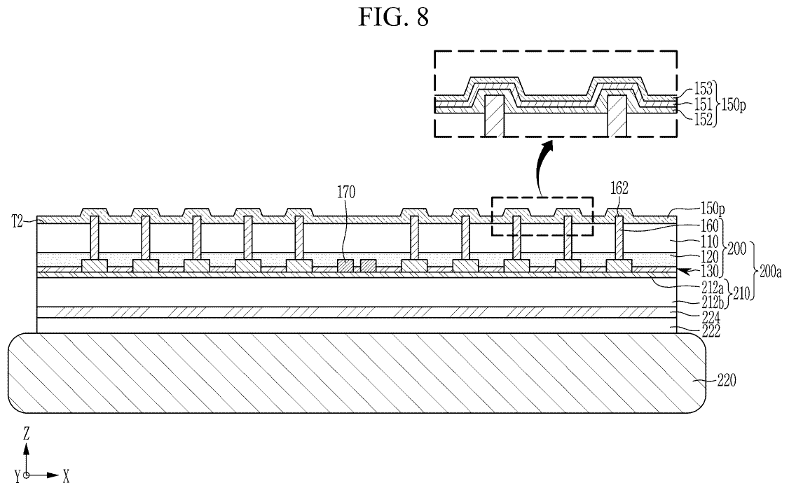

Subsequently, as illustrated in FIG. 8, a preliminary insertion insulation layer 150p may be formed to cover the second surface T2 of the preliminary substrate 200a and the end 162 of the through connector 160.

The preliminary insertion insulation layer 150p may include at least an etch stopping layer, or may include at least a nitride layer (e.g., a silicon nitride layer) that includes nitride (e.g., silicon nitride). For example, the preliminary insertion insulation layer 150p may include a first layer 151, a second layer 152, and a third layer 153. The second layer 152 may include or be formed of nitride (e.g., silicon nitride (SiNx)) and include or be formed of a nitride layer (e.g., a silicon nitride layer). The first layer 151 may include or be formed of an insulating material that is different from a material of the second layer 152, and the third layer 153 may include or be formed of an insulating material that is different from the material of the second layer 152. For example, the first layer 151 and/or the third layer 153 may include or be formed of oxide (e.g., silicon oxide (SiOx)) and include or be formed of an oxide layer (e.g., a silicon oxide layer). The third layer 153 may be used in another process (e.g., a process of forming the dummy pattern 170 etc.), but the third layer 153 may be omitted.

The preliminary insertion insulation layer 150p may be formed by any of various processes (e.g., a deposition process etc.). However, the embodiments are not limited to the process of forming the preliminary insertion insulation layer 150p.

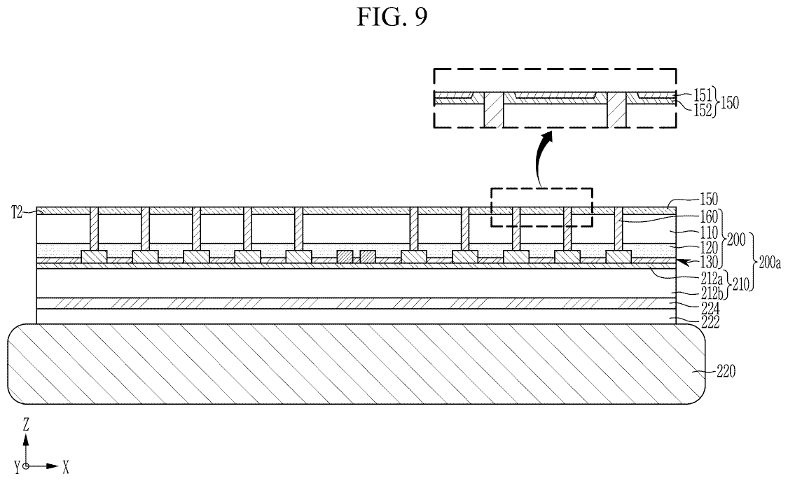

Subsequently, as illustrated in FIG. 9, a planarization process may be performed. In the planarization process, the preliminary substrate 200a may be planarized so that a surface of an insertion insulation layer 150 is disposed on a same plane as the end 162 of the through connector 160.

In the planarization process, a portion of the preliminary insertion insulation layer 150p (refer to FIG. 8) and/or the through connector 160 at a side of the second surface T2 of the preliminary substrate 200a may be removed, and the surface of the insertion insulation layer 150 may be disposed on a same plane as the end 162 of the through connector 160. In one or more embodiments, the planarization process may be performed so that the second layer 152 is disposed at the surface of the insertion insulation layer 150. Thereby, a surface of the second layer 152 and/or a surface of a portion of the first layer 151 may be disposed on a same plane as the end 162 of the through connector 160, and the insertion insulation layer 150 may include the first layer 151 and the second layer 152.

The planarization process may be performed by any of various processes (e.g., a chemical mechanical polishing process etc.). However, the embodiments are not limited thereto, and the planarization process may be performed by any of various processes.

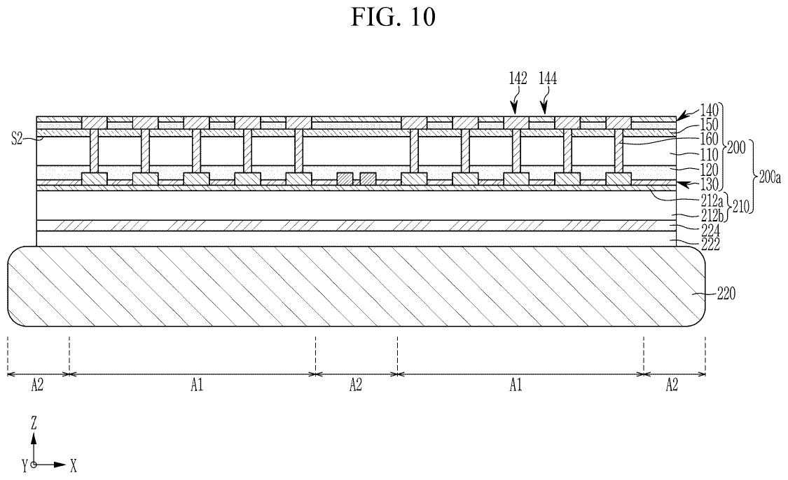

Subsequently, as illustrated in FIG. 10, a second bonding layer 140 that includes a second pad 142 and a second insulation layer 144 may be formed. Thereby, portions that will be included in a plurality of semiconductor devices 10 (refer to FIG. 11) may be disposed in the plurality of active regions A1.

The second pad 142 and the second insulation layer 144 may be formed by any of various processes. For example, a conductive material layer that constitutes the second pad 142 may be formed, a patterning process of the conductive material layer may be performed, an insulating material layer that constitutes the second insulation layer 144 may be formed, and a planarization process may be performed. In one or more embodiments, an insulating material layer that constitutes the second insulation layer 144 may be formed, a patterning process of the insulating material layer may be performed, a conductive material layer that constitutes the second pad 142 may be formed, and a planarization process may be performed. The process of forming the conductive material layer may be performed by any of various processes (e.g., a deposition process, a plating process, etc.), the process of forming the insulating material layer may be performed by any of various processes (e.g., a deposition process etc.), or the planarization process may be performed by any of various processes (e.g., a chemical mechanical polishing process etc.).

In one or more embodiments, the semiconductor device 10 or the preliminary substrate 200a that includes the semiconductor device 10 may have a sufficient thickness capable of being handled by the sacrificial layer 210, and thus, the second pad 142 may be formed on the carrier substrate 220. After forming the semiconductor device 10 that includes the second pad 142, a cutting process, a reconstitution process, and a gap-fill process may be performed. Accordingly, a number of carrier substrates in a manufacturing process of the semiconductor package 100 may be reduced and a manufacturing process may be simplified. Further, a number of an etching process, a chemical mechanical polishing process, a grinding process, etc., performed at the second surface S2 of the substrate 110, before the forming of the second pad 142, may be reduced, thereby minimizing a process error. For example, one thinning process may be performed before the forming of the second pad 142, thereby a process error may be minimized. Accordingly, compared to a process in which a second pad is formed on a reconstitution carrier substrate, a manufacturing process may be simplified and a process error may be reduced.

Subsequently, as illustrated in FIG. 11, a cutting process of individually separating a plurality of semiconductor devices 10 included in the preliminary substrate 200a may be performed. The cutting process may be referred to as a dicing process or a dividing process.

In one or more embodiments, a mask pattern 230 may be formed on the preliminary substrate 200a. The mask pattern 230 may include an opening 230p that exposes a boundary of the plurality of semiconductor devices 10. In the cutting process, the boundary of the semiconductor device 10 may be cut through the opening 230p. After the cutting process, the mask pattern 230 may be removed.

For example, the mask pattern 230 may be formed by forming a photoresist layer that includes a photosensitivity material on the preliminary substrate 200a and performing a patterning process of forming the opening 230p to expose the boundary of the semiconductor device 10. The patterning process of forming the opening 230p may be performed by using a photolithography process. However, the embodiments are not limited thereto, and the mask pattern 230 may include any of various materials or have any of various types. For example, the mask pattern 230 may be a hard mask etc. The cutting process may be performed by any of various processes (e.g., a dry etching process, as an example, a dry etching process using plasma etc.). However, the embodiments are not limited thereto, and the cutting process may be performed by any of various methods. The mask pattern 230 may be removed by any of various process.

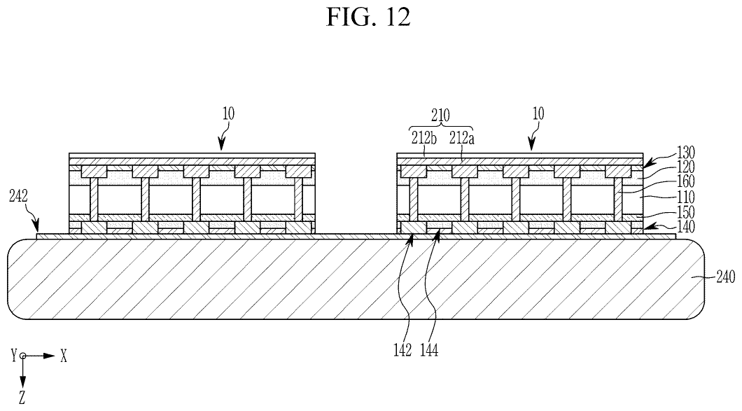

Subsequently, as illustrated in FIG. 12, the semiconductor device 10 may be separated from the carrier substrate 220 (refer to FIG. 11) using the release layer 224 (refer to FIG. 11) and a reconstitution process of bonding (e.g., temporarily or preliminarily bonding) the semiconductor device 10 to a reconstitution carrier substrate 240 may be performed.

The reconstitution carrier substrate 240 may include or be formed of any of various materials. For example, the reconstitution carrier substrate 240 may include or be formed of a semiconductor material, etc., but the embodiments are not limited thereto.

In one or more embodiments, a reconstitution bonding insulation layer 242 may be disposed on the reconstitution carrier substrate 240. The reconstitution bonding insulation layer 242 may include or be formed of an insulating material capable of being bonded to the second bonding layer 140 (e.g., a second bonding insulation layer 144a (refer to FIG. 2)), for example, at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). For example, the reconstitution bonding insulation layer 242 and the second bonding insulation layer 144a may include or be formed of a same insulating material (e.g., silicon carbonitride (SiCNx)). However, the embodiments are not limited thereto.

In the reconstitution process, the semiconductor device 10 may be bonded to the reconstitution carrier substrate 240 in a state that the second bonding layer 140 faces the reconstitution carrier substrate 240 (e.g., the reconstitution bonding insulation layer 242). The second bonding layer 140 (e.g., the second bonding insulation layer 144a) of the semiconductor device 10 and the reconstitution bonding insulation layer 242 that face each other may be bonded to each other by insulation-layer bonding, and the semiconductor device 10 may be bonded to the reconstitution bonding insulation layer 242.

In one or more embodiments, the preliminary substrate 200a may be bonded to the carrier substrate 220 so that the first bonding layer 130 of the preliminary substrate 200a faces the carrier substrate 220 in the process of bonding the preliminary substrate 200a to the carrier substrate 220 (refer to FIG. 6), and the semiconductor device 10 may be bonded to the reconstitution carrier substrate 240 so that the second bonding layer 140 of the semiconductor device 10 faces the reconstitution carrier substrate 240 in the reconstitution process. Accordingly, after the process of bonding the preliminary substrate 200a to the carrier substrate 220, the second surface T2 (refer to FIG. 6) of the preliminary substrate 200a may be exposed, a portion of the substrate 110 may be removed, and the second bonding layer 140 may be formed. A carrier substrate may not be disposed on the second bonding layer 140 of the semiconductor device 10, and the reconstitution process may be performed without transferring to an additional carrier substrate. Accordingly, a number of carrier substrates may be reduced and a number of transfer processes using carrier substrates may be reduced, thereby reducing a process number and process cost may be reduced.

In one or more embodiments, by the reconstitution process, a process error (e.g., overlay mismatch) in a stacking process (e.g., a wafer-on-wafer bonding process) of bonding a plurality of semiconductor portions 100d (refer to FIG. 15) may be reduced. Accordingly, the plurality of semiconductor devices 10 may be arranged or aligned with a small error.

In one or more embodiments, after the reconstitution process, at least a portion of the sacrificial layer 210 that is disposed on the first bonding layer 130 in the thickness direction of the semiconductor device 10 (the Z-axis direction) may be removed. The process of removing at least the portion of the sacrificial layer 210 may be performed using any of various processes (e.g., an etching process, a chemical mechanical polishing process, a grinding process, etc.).

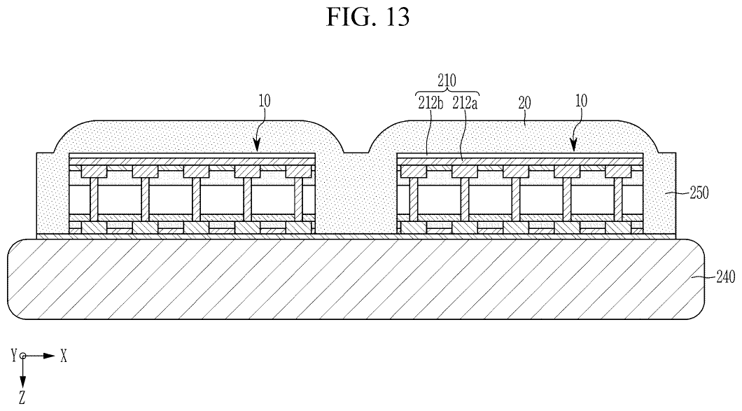

As in the above, a thickness of the sacrificial layer 210 may be reduced before a gap-fill process (refer to FIG. 13 and FIG. 14), and a thickness of the gap-fill layer 250 that is formed in the gap-fill process may be reduced and the gap-fill layer 250 may be stably formed. In one or more embodiments, a portion of the sacrificial layer 210 may be removed on the first bonding layer 130 of the semiconductor device 10 so that the other portion of the sacrificial layer 210 may remain. For example, a portion of the protective sacrificial layer 212a and/or the base sacrificial layer 212b may remain on the first bonding layer 130.

For example, a thickness of the sacrificial layer 210 or the base sacrificial layer 212b may be 10 um or less after removing at least the portion of the sacrificial layer 210. However, the embodiments are not limited thereto, and the thickness of the sacrificial layer 210 or the base sacrificial layer 212b may be greater than 10 um after removing at least the portion of the sacrificial layer 210.

The portion of the sacrificial layer 210 that remains on the first bonding layer 130 may be used as a stopping layer in the gap-fill process, or compensate a process error that may be induced in a chemical mechanical polishing process etc. performed in the gap-fill process. However, the embodiments are not limited thereto.

Subsequently, as illustrated in FIG. 13 and FIG. 14, a gap-fill layer 250 may be formed to fill a space between the plurality of semiconductor devices 10. For example, the gap-fill layer 250 may be formed on the reconstitution carrier substrate 240 and the plurality of semiconductor devices 10 as illustrated in FIG. 13, and the gap-fill layer 250 may be planarized as illustrated in FIG. 14. That is, a semiconductor portion 100d that includes the plurality of semiconductor devices 10 spaced apart from each other in a plan view may be formed by performing the gap-fill process of forming the gap-fill layer 250.

In the semiconductor portion 100d, the plurality of semiconductor devices 10 may be spaced apart from each other in a plan view, and the gap-fill layer 250 may fill a space between the plurality of semiconductor devices 10 and surround an outside of the plurality of semiconductor devices 10. Accordingly, the semiconductor portion 100d may have a shape of a flat plate that includes the plurality of semiconductor devices 10 and the gap-fill layer 250.

In one or more embodiments, the gap-fill layer 250 may include or be formed of an inorganic insulation portion that includes an inorganic insulating material. The gap-fill layer 250 may include or be formed of at least one of oxide, nitride, carbonitride, oxycarbide, oxynitride, and oxycarbonitride. For example, the gap-fill layer 250 may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). For example, the gap-fill layer 250 may include or be formed of silicon oxide (SiOx).

The process of forming the gap-fill layer 250 may be performed by any of various processes (e.g., a deposition process etc.), and the process of planarizing the gap-fill layer 250 may be performed by any of various processes (e.g., a grinding process, a chemical mechanical polishing process, etc.). For example, in the process of planarizing the gap-fill layer 250, a grinding process may be performed and then a chemical mechanical polishing process may be performed. Thereby, process time may be reduced and the gap-fill layer 250 may be stably planarized. However, the embodiments are not limited thereto.

In the process of planarizing the gap-fill layer 250, the portion of the sacrificial layer 210 that remains on the first bonding layer 130 of the semiconductor device 10 may be removed together, the first bonding layer 130 that includes the first pad 132 and the first insulation layer 134 may be exposed to an outside. The portion of the sacrificial layer 210 that remains on the first bonding layer 130 may be used as a stopping layer in the process of planarizing the gap-fill layer 250, or compensate a process error.

A second semiconductor portion 100b (refer to FIG. 15) that includes a plurality of second semiconductor devices 10b (refer to FIG. 16) may be formed by performing the processes described with reference to FIG. 4 to FIG. 14.

A first semiconductor portion 100a (refer to FIG. 15) that includes a plurality of first semiconductor devices 10a (refer to FIG. 16) may be formed by performing the processes described with reference to FIG. 4 to FIG. 10. That is, the first semiconductor portion 100a may be formed without performing the cutting process, the reconstitution process, and the gap-fill process. In the process of forming the first semiconductor portion 100a, the process of forming the sacrificial layer 210 may be omitted. However, the embodiments are not limited thereto, and the process of forming the sacrificial layer 210 may be included. After forming the first semiconductor portion 100a, a process of forming an interconnection member 30 (refer to FIG. 15) may be performed.

A third semiconductor portion that includes a plurality of third semiconductor devices 10c (refer to FIG. 16) may be formed by performing the processes described with reference to FIG. 4 to FIG. 7, and FIG. 11 to FIG. 14. The third semiconductor portion may not include the through connector 160 and the second bonding layer 140. The process of forming the third semiconductor portion may not include processes related to the through connector 160 and the second bonding layer 140.

Among the processes described with reference to FIG. 4 to FIG. 12, the process of preparing the device substrate 200, the process of forming the preliminary substrate 200a, the process of forming the semiconductor device 10 by forming the second bonding layer 140 on the carrier substrate 220, the cutting process to form an individual semiconductor device 10, the process of separating the semiconductor device 10 from the carrier substrate 220, and the process of removing the sacrificial layer 210 may be a manufacturing method of semiconductor device for a reconstitution process.

Subsequently, as illustrated in FIG. 15, a stacking process may be performed. In the stacking process, a second semiconductor portion 100b that is disposed on the reconstitution carrier substrate 240 (refer to FIG. 14) may be bonded to the first semiconductor portion 100a. For example, the stacking process may be performed by a wafer-on-wafer bonding process of bonding semiconductor portions 100d, each being a wafer level that includes a plurality of semiconductor devices 10.

In one or more embodiments, the first semiconductor portion 100a may be disposed on a stacking carrier substrate 260. For example, a release layer 262 may be disposed on the stacking carrier substrate 260, and an interconnection member 30 that is connected to the first semiconductor portion 100a may be disposed on the release layer 262.

The stacking carrier substrate 260 may include or be formed of any of various materials. For example, the stacking carrier substrate 260 may include or be formed of glass, a resin, a semiconductor material, etc. However, the embodiments are not limited to a material of the stacking carrier substrate 260. The release layer 262 may include or be formed of a release material capable of being separated, peeled off, or removed by light, heat, etc. The release layer 262 may include or be formed of any of various release materials, and the embodiments are not limited thereto. An adhesive layer etc. may be further disposed between the stacking carrier substrate 260 and the release layer 262.

In one or more embodiments, the cutting process, the reconstitution process, and the gap-fill process may not be performed to the first semiconductor portion 100a. Accordingly, the first semiconductor portion 100a may have a shape where an outer region A2 is disposed outside the plurality of active regions A1 including a plurality of first semiconductor devices 10a (refer to FIG. 16), respectively. In a stacking process, the first semiconductor portion 100a where the cutting process, the reconstitution process, and the gap-fill process are not performed may be disposed at a lowermost portion, and the stacking process may be stably performed and process cost may be reduced.

By hybrid bonding, the first semiconductor portion 100a and the second semiconductor portion 100b are bonded to each other. In the hybrid bonding, heat and/or pressure is applied to the first semiconductor portion 100a and the second semiconductor portion 100b in a state that the first bonding layer 130 of the second semiconductor portion 100b faces the second bonding layer 140 of the first semiconductor portion 100a. The first pad 132 that is included in the second semiconductor portion 100b may be bonded to the second pad 142 that is included in the first semiconductor portion 100a, and the first insulation layer 134 that is included in the second semiconductor portion 100b may be bonded to the second insulation layer 144 that is included in the first semiconductor portion 100a. After bonding the second semiconductor portion 100b on the first semiconductor portion 100a, the reconstitution carrier substrate 240 (refer to FIG. 14) that is disposed on the second semiconductor portion 100b may be removed.

In one or more embodiments, the semiconductor device 10 may be bonded to the reconstitution carrier substrate 240 so that the second bonding layer 140 of the semiconductor device 10 faces the reconstitution carrier substrate 240 in the reconstitution process, and the semiconductor portion 100d may be bonded to the stacking carrier substrate 260 so that the first bonding layer 130 of the semiconductor portion 100d faces the stacking carrier substrate 260 in the stacking process. Accordingly, a carrier substrate may not be disposed on the first bonding layer 130 of the semiconductor portion 100d in the stacking process, and the stacking process may be performed without transferring to an additional carrier substrate. Accordingly, a number of carrier substrates may be reduced and a number of transfer processes using carrier substrates may be reduced, thereby reducing a process number and process cost may be reduced.

Subsequently, a process of bonding another second semiconductor portion 100b on the second semiconductor portion 100b is repeatedly performed and a plurality of second semiconductor portions 100b may be stacked. Further, a process of bonding a third semiconductor portion on the plurality of second semiconductor portions 100b may be performed. A description with reference to FIG. 15 may be applied to the process of bonding the second semiconductor portion 100b and the process of bonding the third semiconductor portion.

Subsequently, a dividing process may be performed and a second side insulation portion 24 may be formed to form a semiconductor package 100 as illustrated in FIG. 16. In the dividing process, a bonded structure where the second semiconductor portion 100b (refer to FIG. 15) and/or the third semiconductor portion is bonded to the first semiconductor portion 100a (refer to FIG. 15) may be individually divided to correspond to the plurality of active regions A1. Thereby, the semiconductor package 100 may be formed.

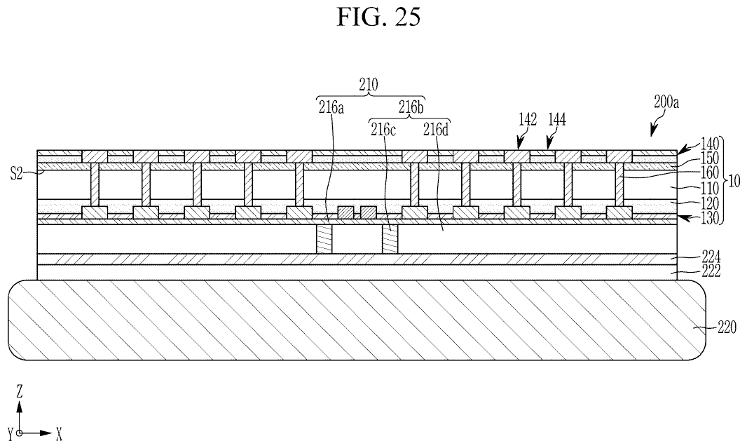

In the dividing process, the substrate 110 may be divided in the first semiconductor portion 100a, and the gap-fill layer 250 (refer to FIG. 25) may be divided in the second semiconductor portion 100b and/or the third semiconductor portion. After the dividing process, the gap-fill layer 250 that is included in the second semiconductor portion 100b and/or the third semiconductor portion on the outer region A2 of the first semiconductor portion 100a may form a first side insulation portion 22. The second side insulation portion 24 may be formed on side surfaces of the first semiconductor device 10a, the second semiconductor device 10b, and the third semiconductor device 10c on the first side insulation portion 22.

For the dividing process, any of various processes may be used. For the process of forming the second side insulation portion 24, any of various processes (e.g., a deposition process etc.) may be used.

In one or more embodiments, after stacking the plurality of semiconductor devices 10 by the wafer-on-wafer bonding process of bonding the plurality of semiconductor portions 100d, each including the plurality of semiconductor devices 10, in the thickness direction of the semiconductor package 100, the dividing process may be performed. Thereby, the plurality of semiconductor packages 100 may be formed. Thereby, a process of the semiconductor package 100 may be simplified. By using the release layer 262 (refer to FIG. 15) that is disposed on the stacking carrier substrate 260 (refer to FIG. 15), the semiconductor package 100 may be separated from the stacking carrier substrate 260.

In one or more embodiments, by using the stacking process of bonding the plurality of semiconductor portions 100d formed through the reconstitution process, a process error may be reduced and productivity may be enhanced.

According to one or more embodiments, by forming the sacrificial layer 210 on the device substrate 200, the semiconductor device 10 may have a sufficient thickness capable of being handled in the reconstitution process. Accordingly, a number, cost, and an error of the manufacturing process of the semiconductor package 100 may be reduced. Thereby, productivity and reliability of the semiconductor package 100 may be enhanced. In a case that a number of the plurality of semiconductor devices 10 included in the semiconductor package 100 increases and a thickness of the semiconductor device 10 decreases, productivity and reliability of the semiconductor package 100 may be maximally enhanced.

On the other hand, in a comparative example, there may be a limit to reducing a thickness of a device substrate in a thinning process of reducing the thickness of the device substrate. That is, in the comparative example, in the thinning process, the thickness of the device substrate may be reduced to be capable of being handled in a reconstitution process. That is, an end of a through connector might not be exposed to an outside in the thinning process. Accordingly, after a cutting process, the reconstitution process, and a gap-fill process, the end of the through connector may be exposed and a second bonding layer may be formed on a reconstitution carrier substrate.

In the comparative example, a first surface of the device substrate where a first bonding layer is disposed is bonded to a carrier substrate in the thinning process, and the first surface of the device substrate is bonded to a reconstitution carrier substrate. Accordingly, a process of attaching an additional carrier substrate to a second surface of the device substrate and a process of removing the additional carrier substrate may be further performed for a transfer from the carrier substrate to the reconstitution carrier substrate. Further, a process of attaching an additional carrier substrate to the second surface of the device substrate and a process of removing the additional carrier substrate may be further performed for a transfer from the reconstitution carrier substrate to a stacking carrier substrate. Accordingly, at least two additional carrier substrates may be needed.

In the comparative example, the second pad is formed after the cutting process and the reconstitution process. Thus, the thinning process, an additional thinning process performed after the reconstitution process, an etch back process of exposing the through connector, and a planarization process of planarizing a gap-fill layer are performed before a process of forming a second pad. Accordingly, a large number of an etching process, a chemical mechanical polishing process, a grinding process, or so on may be performed before the process of forming the second pad. Accordingly, by a process error such as a difference in etching, polishing, or grinding thickness that may be induced in an etching process, a chemical mechanical polishing process, a grinding process, or so on, dishing, erosion, or so on, an end of the through connector may be difficult to be uniformly exposed. Accordingly, a connection property of the through connector and the second pad may be deteriorated.

In the comparative example, an insertion insulation layer is formed on the reconstitution carrier substrate after the cutting process. Accordingly, the insertion insulation layer may have a bent shape that includes portions on a second surface, a side surface, and a first surface of a semiconductor device. That is, the insertion insulation layer may include a portion that is adjacent to the first surface of the semiconductor adjacent to the reconstitution carrier substrate. The insertion insulation layer may be performed after the gap-fill process, and the gap-fill layer may be additionally disposed between the insertion insulation layer and the second pad. As in the above, a shape of the insertion insulation layer in the comparative example may be different from a shape of an insertion insulation layer in an embodiment.

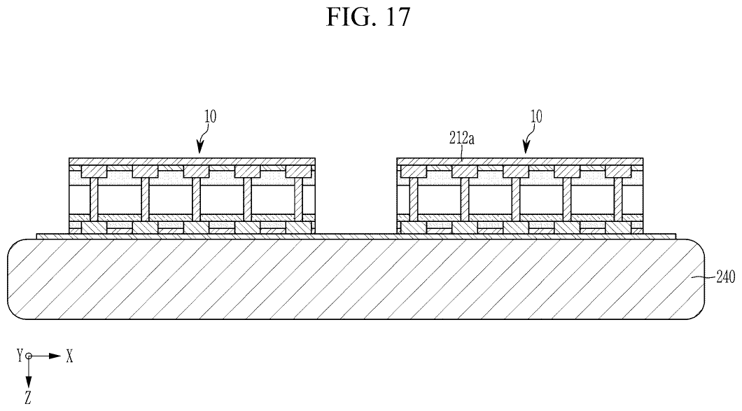

Hereinafter, referring to FIG. 17 to FIG. 27, semiconductor packages and manufacturing methods according to embodiments and modified embodiments will be described. Description of aspects that are the same as or similar to those described above may be omitted.

FIG. 17 is a cross-sectional view a semiconductor package according to one or more embodiments.

As illustrated in FIG. 17, a reconstitution process of bonding (e.g., temporarily or preliminarily bonding) a semiconductor device 10 on a reconstitution carrier substrate 240 may be performed. A description with reference to FIG. 4 to FIG. 12 may be applied to the process of forming the semiconductor device 10 and the reconstitution process of bonding the semiconductor device 10 on the reconstitution carrier substrate 240.

In one or more embodiments, after the reconstitution process, an entirety of a base sacrificial layer 212b (refer to FIG. 12) that is disposed on a first bonding layer 130 (more particularly, on a protective sacrificial layer 212a) may be removed in a thickness direction of the semiconductor device 10 (a Z-axis direction). When the base sacrificial layer 212b is removed before a gap-fill process, a thickness of a gap-fill layer 250 (refer to FIG. 13) that is formed in the gap-fill process may be reduced and the gap-fill layer 250 may be stably formed. In the drawings, it is illustrated as an example that the protective sacrificial layer 212a remains on the first bonding layer 130, but an entirety of the protective sacrificial layer 212a that is disposed on the first bonding layer 130 may be removed.

After the reconstitution process, a semiconductor package may be formed by performing a gap-fill process, a stacking process, a dividing process, etc. A description with reference to FIG. 13 to FIG. 16 may be applied.

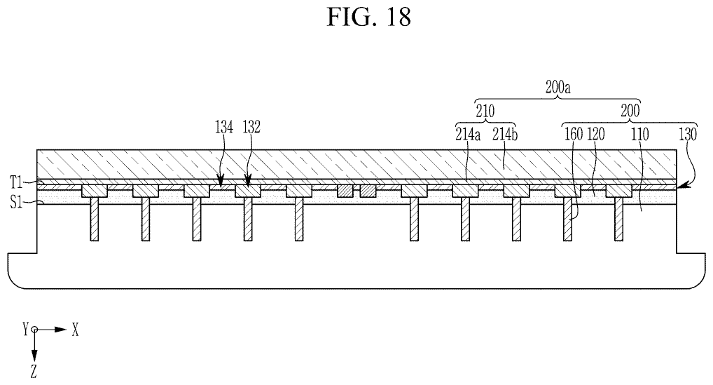

FIG. 18 to FIG. 21 are cross-sectional views illustrating a manufacturing method of a semiconductor package according to one or more embodiments.

As illustrated in FIG. 18, a device substrate 200 may be prepared, and a preliminary substrate 200a may be formed by forming a sacrificial layer 210 on the device substrate 200 (e.g., on a first surface T1 of the device substrate 200 that is adjacent to a first surface S1 of a substrate 110 or on a first bonding layer 130). A description with reference to FIG. 4 may be applied to the device substrate 200.

In one or more embodiments, the sacrificial layer 210 may include a semiconductor substrate 214b, and may further include a bonding sacrificial layer 214a that is disposed on one surface of the semiconductor substrate 214b facing the device substrate 200. For example, the sacrificial layer 210 may be a bonding sacrificial substrate that is bonded to the device substrate 200. More particularly, by insulation-layer bonding between a first insulation layer 134 at or on the first surface T1 of the device substrate 200 and the bonding sacrificial layer 214a, the device substrate 200 and the sacrificial layer 210 of the bonding sacrificial substrate may be bonded to each other. In one or more embodiments, the sacrificial layer 210 that includes the semiconductor substrate 214b manufactured to have a predetermined thickness may be bonded to the device substrate 200. In one or more embodiments, after bonding the sacrificial layer 210 that includes the semiconductor substrate 214b to the device substrate 200, a portion of the semiconductor substrate 214b may be removed to have a predetermined thickness.

The semiconductor substrate 214b may have a relatively large thickness so that the sacrificial layer 210 has a sufficient thickness. The bonding sacrificial layer 214a may be configured to be bonded to the device substrate 200 and/or protect the first surface T1 of the device substrate 200 (e.g., the first bonding layer 130). The bonding sacrificial layer 214a may be referred to as a protective sacrificial layer. In one or more embodiments, the sacrificial layer 210 may include the semiconductor substrate 214b (e.g., the bonding sacrificial substrate) and process time of a process of forming the sacrificial layer 210 may be reduced.

In one or more embodiments, the semiconductor substrate 214b may be a substrate that includes a semiconductor material, or may include a substrate of a semiconductor material and a semiconductor layer on the substrate. For example, the semiconductor substrate 214b may include or be formed of a substrate (e.g., a wafer) that includes or is formed of silicon, germanium, or silicon-germanium having an single-crystalline, polycrystalline, amorphous, or epitaxial structure, or may include or be formed of a silicon on insulator (SOI), a germanium on insulator (GOI), a silicon-germanium on insulator (SGOI), etc. The semiconductor substrate 214b may include or be formed of an undoped semiconductor material. In one or more embodiments, the semiconductor substrate 214b may include or be formed of an n-type or p-type doped semiconductor material.

In one or more embodiments, the bonding sacrificial layer 214a may include or be formed of an insulating material capable of being bonded to the first insulation layer 134. The bonding sacrificial layer 214a may include or be formed of at least one of oxide, nitride, carbonitride, oxycarbide, oxynitride, and oxycarbonitride. For example, the bonding sacrificial layer 214a may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). For example, the bonding sacrificial layer 214a and the first insulation layer 134 may include or be formed of a same insulating material (e.g., silicon carbonitride (SiCNx)). The bonding sacrificial layer 214a may be formed by any of various processes (e.g., a deposition process) performed on the semiconductor substrate 214b.

When the sacrificial layer 210 includes the semiconductor substrate 214b, the sacrificial layer 210 may include a material same as or similar to a material of the substrate 110 that is cut in a cutting process. Thereby, the sacrificial layer 210 (e.g., the semiconductor substrate 214b) may be easily removed in the cutting process, and process time of the cutting process may be reduced. When the bonding sacrificial layer 214a includes or is formed of an insulating material, the bonding sacrificial layer 214a may be easily formed on the semiconductor substrate 214b by a deposition process.

In FIG. 18, it is illustrated as an example that the sacrificial layer 210 includes one semiconductor substrate 214b and one bonding sacrificial layer 214a. However, the embodiments are not limited thereto. The semiconductor substrate 214b may include a plurality of portions or a plurality of substrates that include different materials, or the bonding sacrificial layer 214a may include a plurality of layers, or the bonding sacrificial layer 214a may be omitted. The semiconductor substrate 214b may include or be formed of a material other than the semiconductor material, and the bonding sacrificial layer 214a may include or be formed of any of various materials (e.g., an adhesive material, a bonding material, a sticky material, or an organic material) other than the above insulating material (e.g., an inorganic material).

In one or more embodiments, a thickness of the sacrificial layer 210 or the semiconductor substrate 214b may be 100 um or less (e.g., 20 um to 100 um, as an example, 50 um to 100 um). However, the embodiments are not limited thereto, and the thickness of the sacrificial layer 210 or the semiconductor substrate 214b may be greater than 100 um or less than 50 um (e.g., less than 20 um).

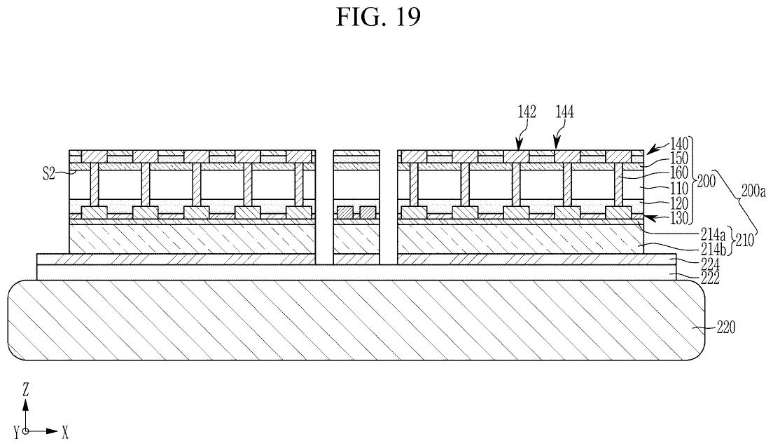

Subsequently, as illustrated in FIG. 19, the preliminary substrate 200a may be bonded (e.g., be temporarily or preliminarily bonded) on the carrier substrate 220. More particularly, the preliminary substrate 200a may be bonded (e.g., be temporarily or preliminarily bonded) on the carrier substrate 220 so that the sacrificial layer 210 (e.g., the bonding sacrificial layer 214a and the semiconductor substrate 214b) of the preliminary substrate 200a faces the carrier substrate 220 (e.g., an adhesive layer 222 and a release layer 224). A semiconductor device 10 (e.g., a plurality of semiconductor devices 10) may be formed by a thinning process, and a process of forming a second bonding layer 140 that includes a second pad 142 and a second insulation layer 144 on a second surface S2 of the substrate 110, and a cutting process may be performed. A description with reference to FIG. 6 to FIG. 11 may be applied.

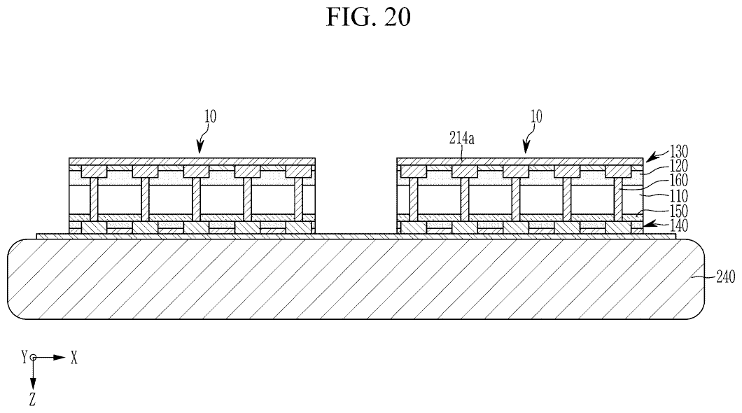

Subsequently, as illustrated in FIG. 20, the semiconductor device 10 may be separated from the carrier substrate 220 (refer to FIG. 19) using the release layer 224 (refer to FIG. 19) and a reconstitution process of bonding (e.g., temporarily or preliminarily bonding) the semiconductor device 10 to a reconstitution carrier substrate 240 may be performed.

In one or more embodiments, after performing the reconstitution process, at least a portion of the sacrificial layer 210 that is disposed on the first bonding layer 130 may be removed in a thickness direction of the semiconductor device 10 (the Z-axis direction). For example, an entirety of the semiconductor substrate 214b may be removed. The process of removing at least the portion of the sacrificial layer 210 may be performed using any of various processes (e.g., an etching process, a chemical mechanical polishing process, a grinding process, etc.).

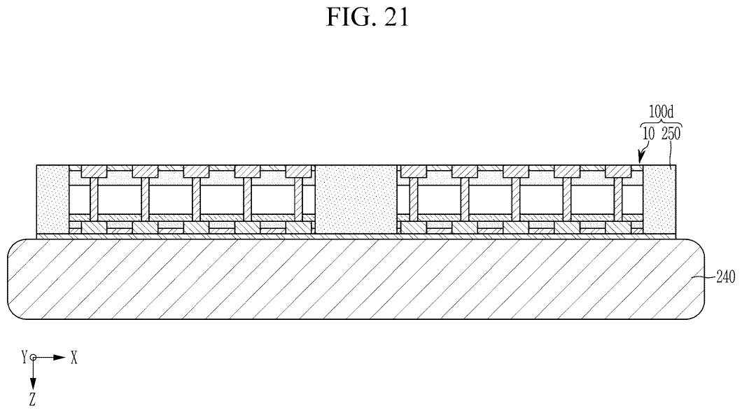

When the semiconductor substrate 214b is removed before the gap-fill process, a thickness of a gap-fill layer 250 (refer to FIG. 21) that is formed in a gap-fill process may be reduced and the gap-fill layer 250 may be stably formed. In the drawings, it is illustrated as an example that the bonding sacrificial layer 214a remains on the first bonding layer 130, but an entirety of the bonding sacrificial layer 214a that is disposed on the first bonding layer 130 may be removed.

Subsequently, as illustrated in FIG. 21, a gap-fill layer 250 may be formed to fill a space between the plurality of semiconductor devices 10. That is, a semiconductor portion 100d that includes the plurality of semiconductor devices 10 spaced apart from each other in a plan view may be formed by performing a gap-fill process of forming the gap-fill layer 250. Subsequently, a semiconductor package may be formed by performing a stacking process, a dividing process, etc. A description with reference to FIG. 15 and FIG. 16 may be applied.

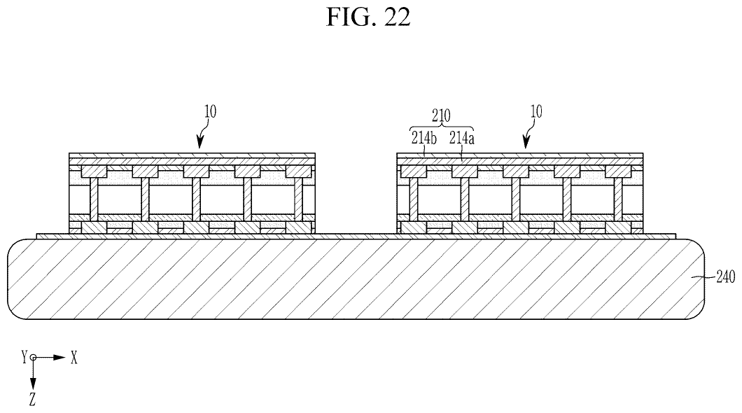

FIG. 22 is a cross-sectional view of a semiconductor package according to one or more embodiments.

As illustrated in FIG. 22, a reconstitution process of bonding (e.g., temporarily or preliminarily bonding) a semiconductor device 10 on a reconstitution carrier substrate 240 may be performed. A description with reference to FIG. 4 to FIG. 12 or a description with reference to FIG. 18 and FIG. 19 may be applied a the process of forming the semiconductor device 10 and the reconstitution process of bonding the semiconductor device 10 on the reconstitution carrier substrate 240.

In one or more embodiments, after the reconstitution process, at least a portion of a sacrificial layer 210 that is disposed on a first bonding layer 130 may be removed in a thickness direction of the semiconductor device 10 (a Z-axis direction in the drawings). A thickness of the sacrificial layer 210 may be reduced before a gap-fill process, and a thickness of a gap-fill layer 250 (refer to FIG. 21) that is formed in the gap-fill process may be reduced and the gap-fill layer 250 may be stably formed. In one or more embodiments, a portion of the sacrificial layer 210 may be removed on the first bonding layer 130 of the semiconductor device 10 so that the other portion of the sacrificial layer 210 may remain. For example, a bonding sacrificial layer 214a and/or a portion of a semiconductor substrate 214b may remain on the first bonding layer 130.

For example, a thickness of the sacrificial layer 210 or the semiconductor substrate 214b may be 10 um or less after removing at least the portion of the sacrificial layer 210. However, the embodiments are not limited thereto, and the thickness of the sacrificial layer 210 or the semiconductor substrate 214b may be greater than 10 um after removing at least the portion of the sacrificial layer 210.

The portion of the sacrificial layer 210 that remains on the first bonding layer 130 may be used as a stopping layer in the gap-fill process, or compensate a process error that may be induced in a chemical mechanical polishing process etc. performed in the gap-fill process.

After the reconstitution process, a semiconductor package may be formed by performing a gap-fill process, a stacking process, a dividing process, etc. The above description may be applied.

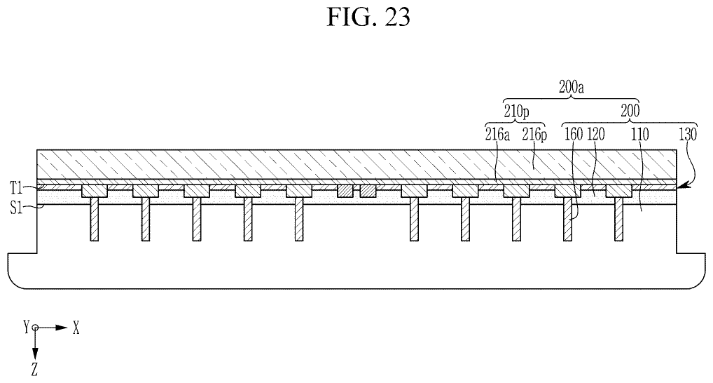

FIG. 23 to FIG. 27 are cross-sectional views illustrating a manufacturing method of a semiconductor package according to one or more embodiments.

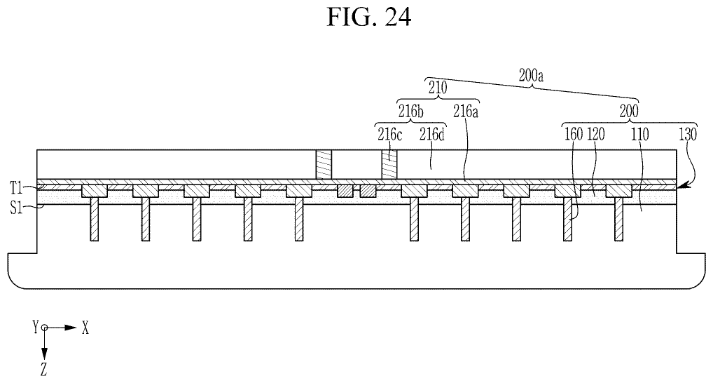

As illustrated in FIG. 23 and FIG. 24, a device substrate 200 may be prepared, and a preliminary substrate 200a may be formed by forming a sacrificial layer 210 on the device substrate 200 (e.g., on a first surface T1 of the device substrate 200 that is adjacent to a first surface S1 of a substrate 110 or on a first bonding layer 130). A description with reference to FIG. 4 may be applied to the device substrate 200.

In one or more embodiments, the sacrificial layer 210 may include a base sacrificial layer 216b that includes a plurality of portions 216c and 216d of different materials in a plan view, and may further include a protective sacrificial layer 216a that is disposed between the base sacrificial layer 216b and the device substrate 200.

For example, the base sacrificial layer 216b may include a first portion 216c that includes a portion cut in a cutting process, and a second portion 216d that includes a material different from a material of the first portion 216c. The first portion 216c may include or be formed of a semiconductor material to be easily cut in the cutting process, and the second portion 216d may include or be formed of an insulating material.

The first portion 216c may include or be formed of a semiconductor sacrificial layer that includes a semiconductor material. The first portion 216c may be a substrate that includes a semiconductor material, may include a substrate of a semiconductor material and a semiconductor layer on the substrate, or may include or be formed of a semiconductor layer formed using a deposition process. For example, the semiconductor substrate 214b may include or be formed of a substrate (e.g., a wafer) that includes or is formed of silicon, germanium, or silicon-germanium having an single-crystalline, polycrystalline, amorphous, or epitaxial structure, may include or be formed of a silicon on insulator (SOI), a germanium on insulator (GOI), a silicon-germanium on insulator (SGOI), etc., or may include or be formed of a semiconductor layer that includes or is formed of silicon, germanium, or silicon-germanium having a polycrystalline, amorphous, or epitaxial structure. The first portion 216c may include or be formed of an undoped semiconductor material. In one or more embodiments, the first portion 216c may include or be formed of an n-type or p-type doped semiconductor material. However, the embodiments are not limited thereto, and the first portion 216c may include or be formed of any of various materials.

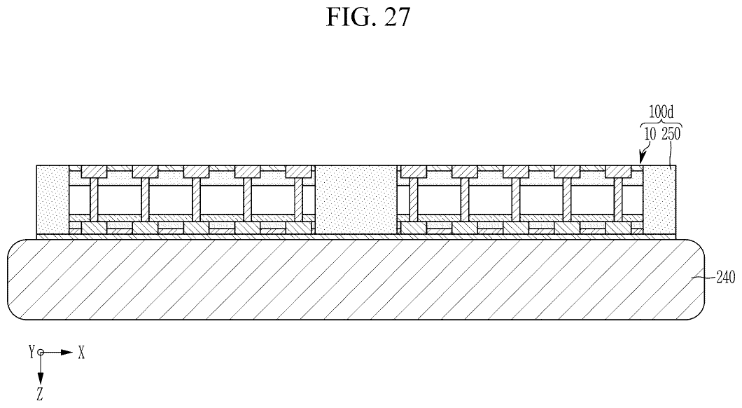

The second portion 216d may include an insulating sacrificial layer that includes or is formed of an insulating material. The insulating sacrificial layer may include or be formed of at least one of oxide, nitride, carbonitride, oxycarbide, oxynitride, and oxycarbonitride. For example, the insulating sacrificial layer may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx). When the insulating sacrificial layer includes or is formed of the above material, the insulating sacrificial layer may have chemical stability and may be formed by an easy process. Further, in a planarization process performed in a gap-fill process, the insulating sacrificial layer may be easily removed together with a gap-fill layer 250 (refer to FIG. 27). However, the embodiments are not limited thereto, and the insulating sacrificial layer may include or be formed of any of various insulating materials.

The protective sacrificial layer 216a may include or be formed of an insulating material that is different from a material of at least a portion of the base sacrificial layer 216b. The protective sacrificial layer 216a may include or be formed of at least one of oxide, nitride, carbonitride, oxycarbide, oxynitride, and oxycarbonitride that is different form a material of at least a portion of the base sacrificial layer 216b. For example, the protective sacrificial layer 216a may include or be formed of at least one of silicon oxide (SiOx), silicon nitride (SiNx), silicon carbonitride (SiCNx), silicon oxycarbide (SiOCx), silicon oxynitride (SiONx), and silicon oxycarbonitride (SiOCNx) that is different from a material of at least a portion of the base sacrificial layer 216b. When the protective sacrificial layer 216a includes or is formed of the above material, the protective sacrificial layer 216a may be easily removed together the gap-fill layer 250 in the planarization process performed in the gap-fill process.

For example, the first portion 216c of the base sacrificial layer 216b may include or be formed of silicon, the second portion 216d of the base sacrificial layer 216b may include or be formed of silicon oxide (SiOx), and the protective sacrificial layer 216a may include or be formed of at least one of silicon nitride (SiNx), silicon carbonitride (SiCNx), silicon oxycarbide (SiOCx), silicon oxynitride (SiONx), and silicon oxycarbonitride (SiOCNx).

In one or more embodiments, the base sacrificial layer 216b that includes the first portion 216c and the second portion 216d, and the protective sacrificial layer 216a may be formed by any of various processes. For example, as illustrated in FIG. 23, a preliminary sacrificial layer 210p may be formed. In one or more embodiments, the preliminary sacrificial layer 210p may be formed by bonding a bonding sacrificial substrate that includes the protective sacrificial layer 216a and a semiconductor substrate 216p to the device substrate 200. In one or more embodiments, the preliminary sacrificial layer 210p may be formed by sequentially forming the protective sacrificial layer 216a and a semiconductor layer using any of various processes (e.g., a deposition process such as a chemical vapor deposition process, etc.) that is performed on the first surface T1 of the device substrate 200. Subsequently, as illustrated in FIG. 24, a portion of the semiconductor substrate 216p (refer to FIG. 23) or the semiconductor layer in the preliminary sacrificial layer 210p (refer to FIG. 23) that corresponds to the second portion 216d may be removed, an insulating material layer may be formed to fill a portion where the semiconductor substrate 216p or the semiconductor layer is removed, and a planarization process may be performed. Thereby, a portion where the semiconductor substrate 216p or the semiconductor layer remains may constitute the first portion 216c, and the insulating material layer in the portion where the semiconductor substrate 216p or the semiconductor layer has been removed may constitute the second portion 216d.

When the first portion 216c includes or is formed of the semiconductor material, the first portion 216c may include a material same as or similar to a material of the substrate 110 cut in the cutting process. Thereby, the first portion 216c may be easily removed in the cutting process, and process time of the cutting process may be reduced. When the second portion 216d includes or is formed of the insulating material, stability may be enhanced in a manufacturing process, and the second portion 216d may act as a stopping layer in an etching process, a chemical mechanical polishing process, a grinding process, etc.

In FIG. 24, it is illustrated as an example that the sacrificial layer 210 includes one base sacrificial layer 216b and one protective sacrificial layer 216a. However, the embodiments are not limited thereto. The base sacrificial layer 216b may include a plurality of layers of different materials in a thickness direction, the protective sacrificial layer 216a may include a plurality of layers of different materials, or the protective sacrificial layer 216a may be omitted. A material of the base sacrificial layer 216b and/or the protective sacrificial layer 216a may be variously modified.

In one or more embodiments, a thickness of the sacrificial layer 210 or the base sacrificial layer 216b may be 100 um or less (e.g., 20 um to 100 um, as an example, 50 um to 100 um). However, the embodiments are not limited thereto, and the thickness of the sacrificial layer 210 or the base sacrificial layer 216b may be greater than 100 um or less than 50 um (e.g., less than 20 um).

In FIG. 23 and FIG. 24, it is illustrated as an example that a portion for the first portion 216c is formed and then a portion for the second portion 216d is formed. However, the embodiments are not limited thereto, and the portion for the second portion 216d may be formed and then the portion for the first portion 216c may be formed.

Subsequently, as illustrated in FIG. 25, the preliminary substrate 200a may be bonded (e.g., be temporarily or preliminarily bonded) on a carrier substrate 220. More particularly, the preliminary substrate 200a may be bonded (e.g., be temporarily or preliminarily bonded) on the carrier substrate 220 so that the sacrificial layer 210 (e.g., the protective sacrificial layer 216a and the base sacrificial layer 216b) of the preliminary substrate 200a faces the carrier substrate 220 (e.g., an adhesive layer 222 and a release layer 224). A semiconductor device 10 (e.g., a plurality of semiconductor devices 10) may be formed by performing a thinning process and forming a second bonding layer 140 that includes a second pad 142 and a second insulation layer 144 on a second surface S2 of the substrate 110. A description with reference to FIG. 6 to FIG. 10 may be applied.

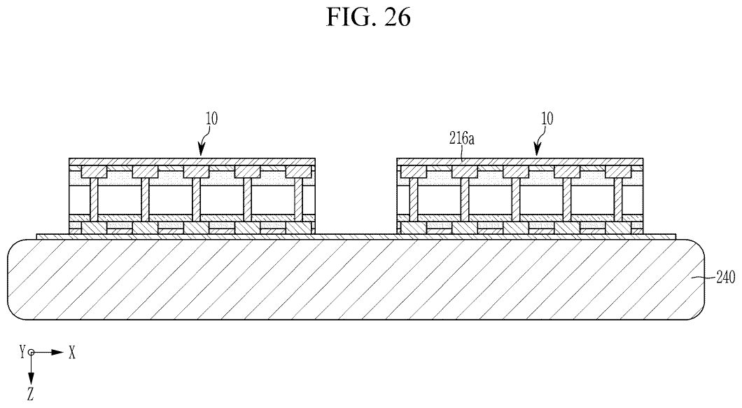

Subsequently, as illustrated in FIG. 26, a cutting process may be performed, the semiconductor device 10 may be separated from the carrier substrate 220 (refer to FIG. 25) using the release layer 224 (refer to FIG. 25), and a reconstitution process of bonding (e.g., temporarily or preliminarily bonding) the semiconductor device 10 to a reconstitution carrier substrate 240 may be performed.

In one or more embodiments, the sacrificial layer 210 (refer to FIG. 25) may include the first portion 216c (refer to FIG. 25) that includes the semiconductor material, and the sacrificial layer 210 (e.g., the first portion 216c) may be easily removed in the cutting process and process time of the cutting process may be reduced.

In one or more embodiments, after performing the reconstitution process, at least a portion of the sacrificial layer 210 that is disposed on the first bonding layer 130 may be removed in the thickness direction of the semiconductor device 10 (the Z-axis direction in the drawings). In FIG. 26, it is illustrated as an example that an entirety of the base sacrificial layer 216b (refer to FIG. 25) is removed and the protective sacrificial layer 216a remains, but the embodiments are is not limited thereto. A portion of the base sacrificial layer 216b may remain, or an entirety of the protective sacrificial layer 216a may be removed.

Subsequently, as illustrated in FIG. 27, a gap-fill layer 250 may be formed to fill a space between the plurality of semiconductor devices 10. That is, a semiconductor portion 100d that includes the plurality of semiconductor devices 10 spaced apart from each other in a plan view may be formed by performing a gap-fill process of forming the gap-fill layer 250. Subsequently, a semiconductor package may be formed by performing a stacking process, a dividing process, etc. A description with reference to FIG. 15 and FIG. 16 may be applied.

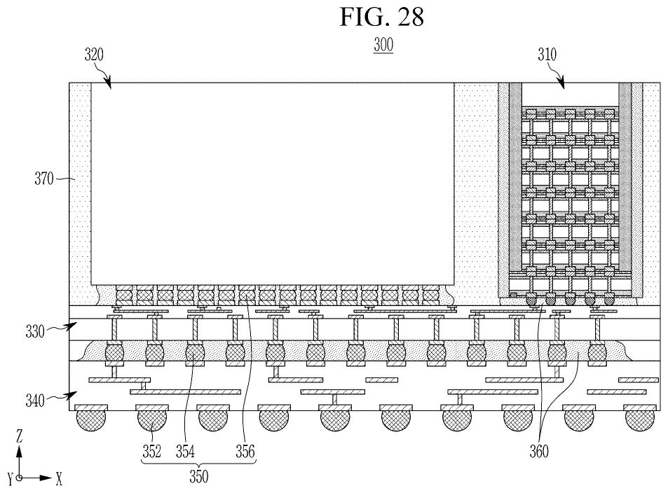

FIG. 28 is a cross-sectional view of a chiplet package including a semiconductor package according to one or more embodiments.

Referring to FIG. 28, a chiplet package 300 according to one or more embodiments may include a first semiconductor chip 310 and a second semiconductor chip 320. The chiplet package 300 may further include a connection substrate 330, a package substrate 340, an interconnection member 350, an underfill layer 360, a molding portion 370, etc.

The first semiconductor chip 310 may be a semiconductor package 100 (e.g., a stacked memory package or a stacked memory chip) described with reference to FIG. 1 to FIG. 27, and the second semiconductor chip 320 may be a logic semiconductor package or a logic semiconductor chip.

The second semiconductor chip 320 may include a central processing unit (CPU), a graphic processing unit (GPU), or an application specific integrated circuit (ASIC). However, the embodiments are not limited thereto, and the second semiconductor chip 320 may have any of various structures or types or may act any of various roles.

The connection substrate 330, the first semiconductor chip 310, and the second semiconductor chip 320 may be disposed on a surface (e.g., an upper surface) of the package substrate 340. For example, the first and second semiconductor chips 310 and 320 may be mounted on the connection substrate 330, the connection substrate 330 on which the first and second semiconductor chips 310 and 320 are mounted may be disposed on the package substrate 340. The first semiconductor chip 310 and the second semiconductor chip 320 that are disposed on the upper surface of the connection substrate 330 may be spaced apart from each other in a horizontal direction. That is, the first semiconductor chip 310 and the second semiconductor chip 320 may be disposed side-by-side on the upper surface of the connection substrate 330.

The package substrate 340 may be structurally support the connection substrate 330, the first semiconductor chip 310, and the second semiconductor chip 320. For example, the package substrate 340 may be a printed circuit board (PCB). The connection substrate 330 may have a finer pitch or include a finer pattern than the package substrate 340. That is, the first and second semiconductor chips 310 and 320 and/or the package substrate 340 may be electrically connected to each other to have a fine pitch or to include a fine pattern using the connection substrate 330. For example, the connection substrate 330 may be an interposer substrate.

The interconnection member 350 may include an outer interconnection member 352, an intermediate interconnection member 354, and a chip interconnection member 356. The outer interconnection member 352 may be disposed at or on one surface (e.g., a lower surface) of the package substrate 340 and be electrically connected to an external circuit, an external device, etc. The intermediate interconnection member 354 may be disposed between the package substrate 340 and the connection substrate 330 and electrically connect the package substrate 340 and the connection substrate 330. The chip interconnection member 356 may electrically connect the first and second semiconductor chips 310 and 320 to the connection substrate 330. The chip interconnection member 356 that is disposed between the first semiconductor chip 310 and the connection substrate 330 may be an interconnection member 30 that is included in the semiconductor package 100, which is described with reference to FIG. 1 to FIG. 27.

The interconnection member 350 may have a shape or a type of a bump, a land, a ball, or a pin. The interconnection member 350 may include or be formed of at least one of tin, lead, bismuth, silver, copper, aluminum, tungsten, nickel, manganese, cobalt, titanium, tantalum, ruthenium, beryllium, indium, molybdenum, magnesium, rhenium, and gallium, or include or be formed of an alloy thereof. For example, the interconnection member 350 may be a solder bump that includes or is formed of tin or that includes or is formed of an alloy that includes tin. However, the embodiments are not limited thereto, and a shape, a type, or a material, etc. of the interconnection member 350 may be variously modified.

The underfill layer 360 may be disposed at a periphery of the intermediate interconnection member 354 and/or at a periphery of the chip interconnection member 356. The underfill layer 360 may include or be formed of a thermosetting resin such as an epoxy resin, a thermoplastic resin such as polyimide, a resin that includes an organic filler or/and a glass fiber, an epoxy molding compound, etc. In one or more embodiments, it is described an example that a first under fill layer is disposed between the first semiconductor chip 310 and the connection substrate 330, and a second underfill layer is disposed between the second semiconductor chip 320 and the connection substrate 330. However, the embodiments are not limited thereto. Accordingly, the first and second semiconductor chips 310 and 320 and the connection substrate 330 may be connected through one underfill layer or one molding portion that is disposed between the first and second semiconductor chips 310 and 320 and the connection substrate 330. In one or more embodiments, a material, a shape, etc. of the underfill layer 360 may be variously modified.

The molding portion 370 that surrounds the first semiconductor chip 310 and the second semiconductor chip 320 on the connection substrate 330 may be further included. For example, the molding portion 370 may entirely cover at least side surfaces of the first and second semiconductor chips 310 and 320 and fill a space between the first semiconductor chip 310 and the second semiconductor chip 320. The molding portion 370 may include or be formed of a thermosetting resin such as an epoxy resin, a thermoplastic resin such as polyimide, a resin that includes an organic filler or/and a glass fiber, an epoxy molding compound, etc. However, the embodiments are not limited thereto, and a shape, a material, etc. of the molding portion 370 may be variously modified.

In FIG. 28, it is illustrated as an example that an upper surface of the first semiconductor chip 310 and an upper surface of the second semiconductor chip 320 are disposed on a same plane, and the molding portion 370 is disposed on side surfaces of the first and second semiconductor chips 310 and 320. However, the embodiments are not limited thereto. For example, at least a portion of the molding portion 370 may be disposed at an upper portion of at least one of the first and second semiconductor chips 310 and 320. In one or more embodiments, the upper surface of the first semiconductor chip 310 and the upper surface of the second semiconductor chip 320 may be disposed on different planes. Other various modifications may be possible.

In FIG. 28, it is illustrated as an example that the chiplet package 300 is a 2.5D semiconductor package in which the first semiconductor chip 310 and the second semiconductor chip 320 disposed next to each other are connected through the connection substrate 330. However, the embodiments are not limited thereto, and the chiplet package 300 may have any of various structures, forms, shapes, or types.

According to one or more embodiments, by forming a sacrificial layer on a device substrate, a semiconductor device may have a sufficient thickness capable of being handled in a reconstitution process. Accordingly, a number, cost, and an error of a manufacturing process of a semiconductor package may be reduced. Thereby, productivity and reliability of the semiconductor package may be enhanced. In a case that a number of a plurality of semiconductor devices included in a semiconductor package increases and a thickness of the semiconductor device decreases, productivity and reliability of the semiconductor package may be maximally enhanced.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor device;
a second semiconductor device on the first semiconductor device and, in a plan view, having an area smaller than an area of the first semiconductor device; and
a side insulation portion on a side surface of the second semiconductor device, the side insulation portion comprising an inorganic insulating material,
wherein each of the first semiconductor device and the second semiconductor device comprises:
a substrate having a first surface and a second surface opposite to the first surface;
a semiconductor device portion on the first surface of the substrate;
a first bonding layer on the semiconductor device portion, the first bonding layer comprising a first pad and a first insulation layer;
an insertion insulation layer on the second surface of the substrate;
a second bonding layer on the insertion insulation layer, the second bonding layer comprising a second pad and a second insulation layer; and
a through connector penetrating the substrate and connecting the semiconductor portion to the second pad or the first pad to the second pad;
wherein the insertion insulation layer comprises a material that is different from a material of at least a portion of the second insulation layer, and
wherein, in the second semiconductor device, an edge of the insertion insulation layer is between the second surface of the substrate and the second bonding layer.

2. The semiconductor package of claim 1, wherein an entirety of the insertion insulation layer of the second semiconductor device is on a same plane.

3. The semiconductor package of claim 1, wherein, in the first semiconductor device, an edge of the insertion insulation layer is between the second surface of the substrate and the second bonding layer.

4. The semiconductor package of claim 1, wherein the insertion insulation layer of the first semiconductor device and the insertion insulation layer of the second semiconductor device have a same shape, and
wherein the insertion insulation layer of the second semiconductor device has an area less than an area of the insertion insulation layer of the first semiconductor device.

5. The semiconductor package of claim 1, wherein an entirety of the insertion insulation layer of the second semiconductor device is substantially parallel to an entirety of the insertion insulation layer of the first semiconductor device.

6. The semiconductor package of claim 1, wherein, in at least one of the first semiconductor device and the second semiconductor device, the second insulation layer comprises a bonding insulation layer and a base insulation layer that is between the bonding insulation layer and the insertion insulation layer, and
wherein, in at least one of the first semiconductor device and the second semiconductor device, the insertion insulation layer comprises a material that is different from at least one of a material of the bonding insulation layer and a material of the base insulation layer.

7. The semiconductor package of claim 1, wherein, in the second semiconductor device, the insertion insulation layer contacts the second bonding layer.

8. The semiconductor package of claim 1, wherein, in at least one of the first semiconductor device and the second semiconductor device, the insertion insulation layer comprises silicon nitride.

9. A method of manufacturing a semiconductor device, the method comprising:
preparing a device substrate comprising a plurality of active regions, the device substrate comprising:
a substrate; and
a semiconductor device portion and a first bonding layer on a first surface of the substrate, wherein the first bonding layer comprises a first pad and a first insulation layer;
forming a preliminary substrate by forming a sacrificial layer on the first bonding layer;
bonding the preliminary substrate to a carrier substrate such that the sacrificial layer faces the carrier substrate;
forming a second bonding layer on a second surface of the substrate, the second bonding layer comprising a second pad and a second insulation layer; and
cutting the preliminary substrate to separate the plurality of active regions.

10. The method of claim 9, wherein the sacrificial layer comprises at least one of an insulating material, a semiconductor material, or a semiconductor substrate.

11. The method of claim 9, wherein the sacrificial layer comprises a plurality of portions in a plan view, and
wherein the plurality of portions comprise different materials.

12. The method of claim 11, wherein the plurality of portions comprise a first portion comprising a semiconductor material, and a second portion comprising an insulating material.

13. A method of manufacturing a semiconductor package, the method comprising:
forming a first semiconductor portion, wherein the first semiconductor portion comprises a plurality of first semiconductor devices;
forming a second semiconductor portion, wherein the second semiconductor portion comprises a plurality of second semiconductor devices; and
bonding the second semiconductor portion on the first semiconductor portion,
wherein the forming of the second semiconductor portion comprises:
preparing a device substrate, wherein the device substrate comprises a substrate, and a semiconductor device portion and a first bonding layer on a first surface of the substrate, the first bonding layer comprising a first pad and a first insulation layer;
forming a preliminary substrate by forming a sacrificial layer on the first bonding layer;
preliminarily bonding the preliminary substrate to a carrier substrate such that the sacrificial layer faces the carrier substrate;
forming a second bonding layer on a second surface of the substrate, the second bonding layer comprising a second pad and a second insulation layer;
cutting the preliminary substrate to separate the plurality of second semiconductor devices;
bonding the plurality of second semiconductor devices to a reconstitution carrier substrate such that the second bonding layer of each of the plurality of second semiconductor devices faces the reconstitution carrier substrate; and
forming a gap-fill layer in at least one space between the plurality of second semiconductor devices on the reconstitution carrier substrate, and
wherein the gap-fill layer comprises an inorganic insulating material.

14. The method of claim 13, wherein the sacrificial layer comprises at least one of an insulating material, a semiconductor material, or a semiconductor substrate.

15. The method of claim 13, wherein the sacrificial layer comprises a plurality of portions in a plan view, and
wherein the plurality of portions include different materials.

16. The method of claim 15, wherein the plurality of portions comprise a first portion comprising a semiconductor material and a second portion comprising an insulating material.

17. The method of claim 13, further comprising:
after the bonding of the plurality of second semiconductor devices to the reconstitution carrier substrate, removing the sacrificial layer,
wherein the cutting of the preliminary substrate, the bonding of the plurality of second semiconductor devices to the reconstitution carrier substrate, and the forming of the gap-fill layer are performed after the forming of the second bonding layer.

18. The method of claim 13, further comprising, after the preliminarily bonding of the preliminary substrate and before the forming of the second bonding layer:
removing a portion of the substrate at the second surface of the substrate; and
forming an insertion insulation layer on the second surface of the substrate,
wherein, after the removing of the portion of the substrate, an end of a through connector is exposed and protrudes from the second surface of the substrate, and
wherein, in the forming of the insertion insulation layer, a surface of the insertion insulation layer is on a same plane as the end of the through connector.

19. The method of claim 18, wherein the insertion insulation layer comprises silicon nitride, and
wherein, in the forming of the second bonding layer, the insertion insulation layer is used as an etch stopping layer.

20. The method of claim 13, further comprising:
dividing a bonded structure that comprises the first semiconductor portion and the second semiconductor portion that are bonded to each other into a plurality of semiconductor packages,
wherein the first semiconductor portion comprises a plurality of active regions and an outer region outside the plurality of active regions,
wherein the plurality of active regions correspond to the plurality of first semiconductor devices, respectively,
wherein the outer region comprises the substrate, and
wherein the dividing of the bonded structure comprises dividing the substrate of the first semiconductor portion and the gap-fill layer.
